(19) United States
(12) Patent Application Publication
(10) Pub. No.: US 2025/0056683 A1
(43) Pub. Date: Feb. 13, 2025

(54) SENSOR DEVICE AND COOKING APPLIANCE INCLUDING THE SAME

(71) Applicant: SAMSUNG ELECTRONICS CO., LTD., Suwon-si (KR)

(72) Inventors: Hyunjoon CHOO, Suwon-si (KR); Sanguk PARK, Suwon-si (KR); Jungsu HA, Suwon-si (KR); Geun KANG, Suwon-si (KR); Jaeyong KO, Suwon-si (KR); Youngkun KWON, Suwon-si (KR); Chulyong JUNG, Suwon-si (KR); Jonghun HA, Suwon-si (KR)

(73) Assignee: SAMSUNG ELECTRONICS CO., LTD., Suwon-si (KR)

(21) Appl. No.: 18/767,395

(22) Filed: Jul. 9, 2024

Related U.S. Application Data
(63) Continuation of application No. PCT/KR2024/008645, filed on Jun. 21, 2024.

(30) Foreign Application Priority Data
Aug. 7, 2023 (KR) 10-2023-0103136
Jan. 5, 2024 (KR) 10-2024-0002531

(51) Int. Cl. H05B 6/06; G01K 1/16; G01K 7/01

(52) U.S. Cl. CPC H05B 6/06; G01K 1/16; G01K 7/01

(57) ABSTRACT

A sensor device according to an embodiment, mountable on a cooking vessel to measure a temperature of a food item in the cooking vessel heated by a heating device. The sensor device includes a heat transfer portion to receive heat from the heated cooking vessel while the sensor device is mounted to the cooking vessel, a thermoelectric element to generate a current and electrical energy based on the heat transferred from the heat transfer portion, a printed board assembly (PBA) to which the current generated by the thermoelectric element is applied, an energy storage portion electrically connected to the PBA to store the electrical energy received from the PBA, a sensor body on which the PBA and the energy storage portion are disposed, a probe mountable on the sensor body, the probe including a temperature sensor to measure the temperature of the food item in the cooking vessel.

### CROSS REFERENCE TO THE RELATED APPLICATION

This application is a continuation application, filed under 35 U.S.C. § 111 (a), of International Application PCT/KR2024/008645 filed Jun. 21, 2024, and is based on and claims priority under 35 U.S.C. § 119 to Korean Patent Applications No. 10-2023-0103136, filed on Aug. 7, 2023, and Korean Patent Applications No. 10-2024-0002531, filed on Jan. 5, 2024 in the Korean Intellectual Property Office, the disclosures of which are incorporated by reference herein in their entireties.

### TECHNICAL FIELD

The disclosure relates to a sensor device for measuring the temperature of food and a cooking appliance including the same.

### BACKGROUND ART

In general, a cooking appliance may include a heating device, such as an induction heater. The heating device may usually heat a cooking vessel using the principle of induction heating for cooking.

Food in a cooking vessel may boil over or burn when the cooking vessel is heated excessively. A sensor device may prevent such a situation by, for example, detecting the temperature of the food and controlling the heating power of the heating device.

The sensor device may be used to measure the temperature of the food. The sensor device may be charged by a wired or by a wireless charger connected to a power source by a wire.

Therefore, the sensor device requires charging before use, and because the sensor device is used in a high temperature environment, the wired cable or wireless charger cable may be a potential fire hazard.

### SUMMARY

One aspect of the present disclosure provides a sensor device capable of measuring the temperature of a food item.

Further, one aspect of the present disclosure provides a sensor device that is charged by receiving heat from an external source.

Further, one aspect of the present disclosure provides a sensor device capable of being charged simultaneously with temperature measurement.

Technical tasks to be achieved in this document are not limited to the technical tasks mentioned above, and other technical tasks not mentioned will be clearly understood by those skilled in the art from the description below.

A sensor device according to an embodiment of the present disclosure, mountable on a cooking vessel to measure the temperature of a food item accommodated in the interior of the cooking vessel heated by a heating device, the sensor device including: a thermoelectric element generating a potential difference due to a temperature difference, a printed board assembly to which current generated by the thermoelectric element is applied, an energy storage portion electrically connected to the printed board assembly, a sensor body in which the printed board assembly and the energy storage portion are disposed, a probe mounted on the sensor body and including a temperature sensor to measure the temperature of the food item accommodated in the cooking vessel, and a heating portion configured to transfer heat generated from an external source to the thermoelectric element.

A cooking appliance according to an embodiment of the present disclosure includes a heating device mountable on a cooking vessel thereon and heating the cooking vessel, and a sensor device mountable on the cooking vessel, wherein the sensor device including a thermoelectric element generating a potential difference due to a temperature difference, a printed board assembly to which current generated by the thermoelectric element is applied, an energy storage portion electrically connected to the printed board assembly, a sensor body in which the printed board assembly and the energy storage portion are disposed, a probe mounted on the sensor body and including a temperature sensor to measure the temperature of the food item in the cooking vessel, and a heat transfer portion configure to transfer heat from the heating device or from the cooking vessel heated by the heating device to the thermoelectric element.

A sensor device may be mountable on a cooking vessel to measure a temperature of a food item in the cooking vessel heated by a heating device, the sensor device comprising: a heat transfer portion to receive heat from the heated cooking vessel while the sensor device is mounted to the cooking vessel; a thermoelectric element to generate a current and electrical energy based on the heat transferred from the heat transfer portion; a printed board assembly (PBA) to which the current generated by the thermoelectric element is applied; an energy storage portion electrically connected to the PBA to store the electrical energy received from the PBA; a sensor body on which the PBA and the energy storage portion are disposed; and a probe mountable on the sensor body, the probe including a temperature sensor to measure the temperature of the food item in the cooking vessel.

The heat transfer portion may be spaced apart from the probe to allow a part of the cooking vessel to be positioned between the probe and the heat transfer portion.

The heat transfer portion may be in contact with the part of the cooking vessel to conduct the heat from the cooking vessel.

The probe may extend from the sensor body along one direction, and the heat transfer portion extends from the sensor body and in parallel to the probe.

The heat transfer portion may include a heat pipe configured to transfer the heat transferred from the cooking vessel to the thermoelectric element.

The sensor device may further comprise a cover configured to cover at least a portion of the heat transfer portion and be mounted to the cooking vessel.

The cover may be mountable on the cooking vessel, and the cover includes a mounting slot in which a heat conductor is disposed to conduct the heat from the cooking vessel.

The heat transfer portion may include a heat generating portion to be placed adjacent to the heating device to be heated by the heating device.

The heat transfer portion may further include a heat pipe through which the heat generated by the heat generating portion is transferred to the thermoelectric element.

The heat transfer portion may extend from the sensor body and is supported on the heating device.

The sensor device may further comprise a supporter configured to enclose the heat transfer portion.

The thermoelectric element may be in contact with the heat transfer portion to allow the heat generated in the heat transfer portion to be transferred to the thermoelectric element.

The heating device may include an induction heating device, and the heat transfer portion includes a magnetic material to enable heat to be generated by the induction heating device.

The heat transfer portion may include: a heat generating portion to be placed adjacent to the induction heating device and formed of the magnetic material; and a heat pipe configured to transfer the heat generated in the heat generating portion to the thermoelectric element.

The energy storage portion may include a super capacitor.

A rechargeable sensor device may be mountable on a cooking vessel to measure a temperature of a food item in the cooking vessel heated by the heating device, the sensor device comprising: a sensor body; a heat transfer portion extending from the sensor body, and to receive heat from the cooking vessel while the sensor device is mounted to the cooking vessel; a thermoelectric element included in the sensor body, connected to the thermoelectric element, and to convert thermal energy from the received heat into electrical energy; an energy storage portion included in the sensor body, and to store the converted electrical energy to charge the rechargeable sensor device; and a probe mountable on the sensor body, the probe including a temperature sensor to measure the temperature of the food item in the cooking vessel.

The temperature sensor may be powered on and operated using the electrical energy stored in the energy storage portion.

### DESCRIPTION OF DRAWINGS

FIG. 1 is a view illustrating a cooking vessel placed on a heating device and a sensor device mounted on the cooking vessel.

FIG. 2 is a view illustrating the sensor device according to an embodiment.

FIG. 3 is a longitudinal cross-sectional view illustrating the sensor device of FIG. 2.

FIG. 4 and FIG. 5 are views illustrating the sensor device held on the cooking vessel and a direction of heat movement to describe a power generation and charging process.

FIG. 6 is a control block diagram for explaining an operation of the sensor device and the heating device according to an embodiment.

FIG. 7 is a flowchart illustrating the operation of the sensor device and the heating device according to an embodiment.

FIG. 8 is a view illustrating the sensor device according to an embodiment with a heat pipe disposed within a probe.

FIG. 9 is a view illustrating a sensor device in which the length of the heat pipe is adjustable.

FIG. 10 is a view illustrating a sensor device having a bendable end of the probe, wherein the sensor device is mounted on the cooking vessel to measure the temperature of the food item.

FIG. 11 is a view illustrating an induction heating device, a cooking vessel placed on the induction heating device, and a sensor device mounted to the cooking vessel, according to an embodiment of the present disclosure.

FIG. 12 is an exploded view illustrating a cooking plate disassembled from the induction heating device of FIG. 11.

FIG. 13 is a perspective view illustrating the sensor device according to an embodiment of the present disclosure.

FIG. 14 is a cross-sectional view illustrating the sensor device of FIG. 13 placed on the cooking vessel.

FIG. 15 is a perspective view illustrating a sensor device according to an embodiment of the present disclosure.

FIG. 16 is a cross-sectional view illustrating the sensor device of FIG. 15 held on the cooking vessel.

FIG. 17 is a cross-sectional view illustrating the sensor device of FIG. 16 held on the cooking vessel, according to an embodiment of the present disclosure.

FIG. 18 is a cross-sectional view illustrating a sensor device mounted to the cooking vessel, according to an embodiment of the present disclosure.

### MODES OF THE INVENTION

Embodiments described in the disclosure and configurations shown in the drawings are merely examples of the embodiments of the disclosure and may be modified in various different ways at the time of filing of the present application to replace the embodiments and drawings of the disclosure.

In addition, the same reference numerals or signs shown in the drawings of the disclosure indicate elements or components performing substantially the same function.

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “including”, “having”, and the like are used to specify features, numbers, steps, operations, elements, components, or combinations thereof, but do not preclude the presence or addition of one or more of the features, numbers, steps, operations, elements, components, or combinations thereof. The expression “at least one of A, B and C” may include any of the following: A, B, C, A and B, A and C, B and C, A and B and C.

It will be understood that, although the terms “first”, “second”, “primary”, “secondary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

In the following detailed description, the terms of “front”, “forward”, “rear”, “backward”, “top”, “bottom”, “upper”, “lower”, “left”, and “right” may be defined by the drawings, but the shape and the location of the component is not limited by the term.

Hereinafter, various embodiments according to the disclosure will be described in detail with reference to the accompanying drawings.

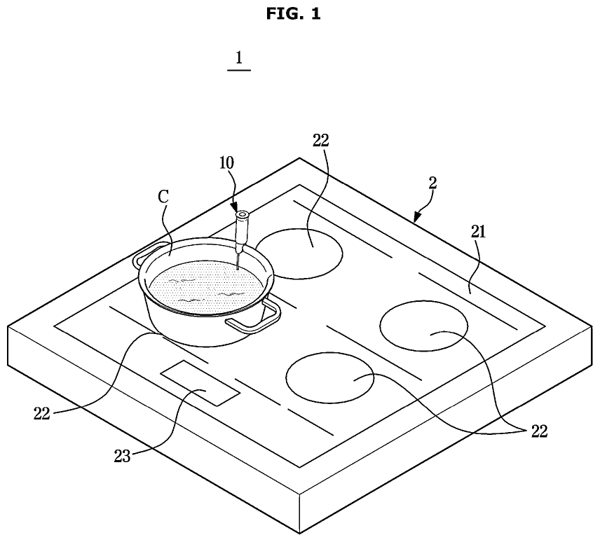

FIG. 1 is a view showing a cooking vessel placed on a heating device and a sensor device mounted on the cooking vessel.

A cooking appliance 1 may include a heating device 2 and a sensor device 10. The heating device 2 may heat a cooking vessel (also referred to as a cookware) C and a food to be cooked (hereinafter referred to as a food item) in the cooking vessel C. The heating device 2 may be an induction heating device, but is not limited thereto. For example, the heating device 2 may include a gas burner, a hot plate, a highlighter, or the like. A hot plate may be a heating device in which heat is generated from a hot iron plate itself, and a highlighter may be a heating device in which heat is emitted by a heating wire under a ceramic plate. Hereinafter, the heating device 2 will be described as an induction heating device.

The heating device 2 may include a cooking plate 21 on which the cooking vessel C may be placed. The cooking plate 21 may have magnetic properties to enable the cooking vessel C to be inductively heated. An alternating current (AC) may be supplied to a coil of the cooking plate 21, and a time-varying magnetic field may be induced in the coil. When the magnetic field passes through the metal forming the cooking vessel C, an eddy current may be generated by the resistance of the metal (e.g., iron) of the cooking vessel C. The eddy current generated in the cooking vessel C may generate heat in the cooking vessel C, thereby heating the food item therein.

The cooking vessel C may include a pot, a frying pan, a steamer, a rice cooker, or the like, and the type of cooking vessel C is not limited thereto. A pot will be described herein as an example.

The heating device 2 may include a cooking zone 22 arranged on at least a portion of the cooking plate 21. The cooking zone 22 may be arranged on an upper side of the coil. The cooking vessel C placed on the cooking zone 22 may be heated by an electromagnetic induction phenomenon. The cooking zone 22 may be provided in a plurality.

An upper surface of the cooking plate 21 may be arranged in the shape of a flat plate on which the cooking vessel C may be placed. The cooking plate 21 may be made of tempered glass, such as ceramic glass, to prevent the cooking plate from being easily damaged.

The heating device 2 may include a control panel 23 for controlling the heating power of the cooking zones 22. The control panel 23 may turn the power of the heating device 2 on and off. In addition, the control panel 23 may control the heating power of the cooking zones 22. The control panel 23 may be provided as a touch panel, but is not limited thereto. For example, the control panel 23 may be provided in various ways, such as a touch screen, buttons, or the like.

The control panel 23 may provide a user interface for interacting with the user and the cooking appliance 1. The user interface may be arranged on one side of the cooking zones 22 of the cooking plate 21. The user interface may receive control commands from the user and may display operational information of the cooking appliance 1. The user interface may include at least one input interface 23b (inputter 23b) and at least one output interface 23a (outputter 23a). However, the location of the user interface may not be limited to being on the cooking plate 21, and may be arranged at various locations, such as on the front or side of the cooking appliance 1.

At least a portion of the sensor device 10 may be located on the inside of the cooking vessel C. The sensor device 10 may be inserted into the food item to detect the temperature of the food item. In particular, the sensor device 10 may be inserted into the food item while it is mounted on the side of the cooking vessel C to detect the temperature of the food item.

The sensor device 10 may be used while mounted on the cooking vessel C. Accordingly, user convenience may be improved as the user does not need to hold the sensor device 10 separately.

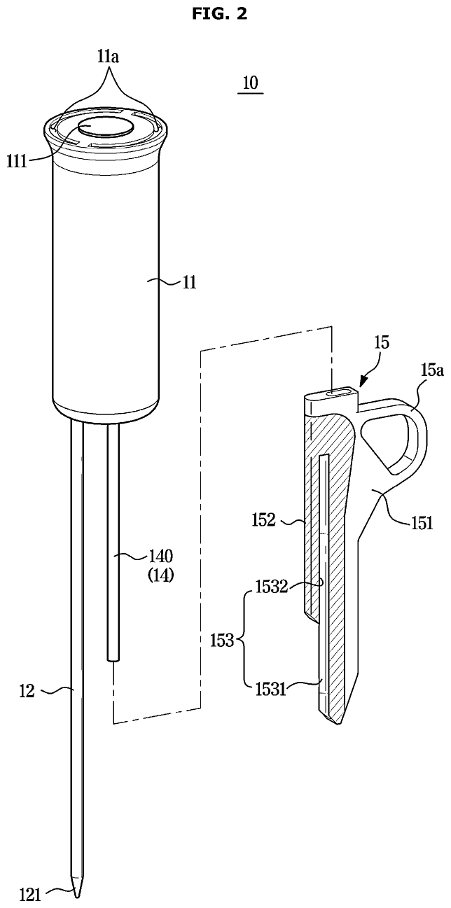

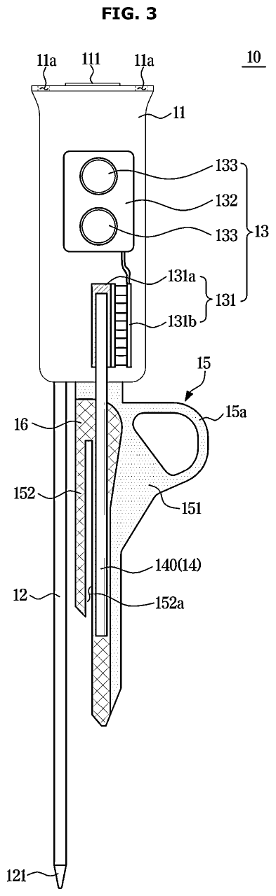

FIG. 2 is a view showing the sensor device according to an embodiment. FIG. 3 is a longitudinal cross-sectional view showing the sensor device of FIG. 2.

Referring to FIGS. 2 and 3, the sensor device 10 may include a sensor body 11 arranged to be held by the user. A power generation portion 13, which will be described later, may be installed within the sensor body 11.

The sensor body 11 may include an input interface 111 or an inputter 111 that allows the user to make an input in order to pair the sensor device 10 with the heating device 2. The input interface 111 may be located on an upper side of the sensor body 11. The input interface 111 may be provided as a button, but is not limited thereto. The input interface 111 may be provided as a touch panel, a switch, or the like.

The sensor body 11 may include a heat dissipation hole 11a through which steam or the like generated in the cooking vessel C may be discharged. The heat dissipation hole 11a may be formed around the input interface 111, or may be formed at an upper end of a side portion of the sensor body 11. The heat dissipation hole 11a may be formed not only as a hole, but also as a mesh or slit shape.

In FIGS. 2 and 3, the heat dissipation holes 11a are shown to be formed in the shape of a semicircular slit around the input interface 111, but the present disclosure is not limited thereto.

The sensor device 10 may include a probe 12 extending from the sensor body 11 to detect the temperature of the food item. The probe 12 may include a temperature sensor 121 therein. The temperature sensor 121 may be provided at one end of the probe 12. That is, the temperature sensor 121 may be located on an opposite side of the probe 12 from where the probe 12 is secured to the sensor body 11.

The temperature sensor 121 may be a thermistor whose resistance value changes as a function of temperature. In particular, the temperature sensor 121 may be a negative temperature coefficient (NTC) thermistor. However, the present disclosure is not limited thereto and may be a positive temperature coefficient (PTC) thermistor or may be provided as any other type of temperature sensor.

The probe 12 may be formed from a metal material that is resistant to heat. For example, the probe 12 may be formed from stainless steel, but is not limited thereto. In addition, the probe 12 may be formed of a waterproof material to prevent liquids from seeping into the interior of the probe 12.

The probe 12 may be detachably coupled to the sensor body 11. In particular, one end of the probe 12 may be detachably coupled to the sensor body 11.

The probe 12 may be provided in the form of a rod. The probe 12 may be formed with a pointed end, i.e., the portion where the temperature sensor 121 is located, to allow the pointed end to be inserted into a food product, such as meat, fish, or the like. However, the present disclosure is not limited thereto, and the probe 12 may also measure the temperature of liquid food, such as broth, soup, stew, or the like.

The sensor device 10 may include the power generation portion 13 disposed within the sensor body 11. The power generation portion 13 may include a thermoelectric element 131 that generates a potential difference due to a temperature difference. The thermoelectric element 131 may be configured to convert thermal energy to electrical energy. In addition, the power generation portion 13 may include a printed board assembly (PBA) 132 that increases the potential difference generated by the thermoelectric element 131, and an energy storage portion 133 that is electrically connected to the PBA 132 to store the converted electrical energy. In one example, the energy storage portion 133 may be referred to and characterized as a battery.

The thermoelectric element 131 may include a heat absorbing plate 131a to absorb heat and a heat dissipating plate 131b to dissipate heat. The heat dissipating plate 131b may function as a heat sink.

The heat absorbing plate 131a may be connected to a heat pipe 140, which will be described later. The heat absorbing plate 131a may receive heat from the heat pipe 140 to form a temperature difference with the heat dissipating plate 131b. The thermoelectric element 131 may be subject to the Seebeck effect, where the temperature difference generates an electromotive force. Electrons may move inside the thermoelectric element 131. This may refer to that current may flow in the thermoelectric element 131.

The thermoelectric element 131 may be electrically connected to the PBA 132. Current generated in the thermoelectric element 131 may flow to the PBA 132. The PBA 132 may be a step-up circuit. The electromotive force output from the thermoelectric element 131 may be relatively small. Accordingly, the electromotive force generated by the thermoelectric element 131 may be increased by the step-up circuit. The increased electromotive force may charge the energy storage portion 133.

The energy storage portion 133 may be a capacitor. However, the present disclosure is not limited thereto and the energy storage portion 133 may include different chemical batteries. For example, the energy storage portion 133 may be configured as a lithium ion battery, a nickel cadmium battery, or the like. However, due to the nature of use in a high temperature environment, it is preferred to be configured as a capacitor.

The energy storage portion 133 may be a super capacitor. The super capacitor may refer to a capacitor that has a larger storage capacity than a conventional capacitor. In addition, the super capacitor has the advantage that it may be charged and discharged very quickly, may be charged and discharged many times, and may be used semi-permanently.

The sensor device 10 may include a heat transfer portion 14 configured to transfer heat generated from an external source to the thermoelectric element 131. For example, the external source may be the heated cooking vessel C or the heating device 2. However, the present disclosure is not limited thereto, and the external source may be provided in any manner as long as it may generate heat or transfer heat.

The heat transfer portion 14 may include the heat pipe 140 arranged to receive heat from the cooking vessel C. The heat pipe 140 may be arranged to be in contact with the cooking vessel C. In other words, heat from the cooking vessel C may be conducted to the heat pipe 140. The conducted heat may be transferred to the heat absorbing plate 131a of the thermoelectric element 131.

However, the present disclosure is not limited thereto, and the heat transfer portion 14 may be provided in a variety of ways, such as a metal rod capable of conducting heat. In other words, the heat transfer portion 14 may be provided in any manner as long as it may be in contact with the cooking vessel C to receive heat.

The heat pipe 140 may extend from the sensor body 11. The heat pipe 140 may extend in parallel to the probe 12. The heat pipe 140 may be arranged to be spaced apart from the probe 12 by a predetermined distance.

A side of the cooking vessel C may be positioned between the probe 12 and the heat pipe 140. In other words, the probe 12 may be positioned on the inside the cooking vessel C, and the heat pipe 140 may be positioned on the outside of the cooking vessel C. By positioning the probe 120 and the heat pipe 140 respectively inside and outside the cooking vessel C, the sensor device 10, i.e., the probe 12, may be mounted on the side of the cooking vessel C.

The probe 12 may measure the temperature of the food item inside the cooking vessel C. Meanwhile, the heat pipe 140 may be in contact with the heated cooking vessel C, so that heat may be transferred to the heat pipe 140.

Heat may be transferred to the heat pipe 140 by conduction and convection. The heat pipe 140 may be configured as a metal pipe with a vacuum inside and a small amount of refrigerant contained therein. For example, a pipe made of copper, which has a high thermal conductivity, may contain a small amount of water.

However, the present disclosure is not limited thereto, and the heat pipe 140 may be a metal rod that transfers heat only by conduction. The heat pipe 140 may be formed of copper, silver, or the like, which has a high thermal conductivity.

When a temperature difference occurs between a heated portion and a cooled portion of a portion of the heat pipe 140, heat may be transferred by convection of the refrigerant. In the present embodiment, heat conducted from a wall surface of the cooking vessel C may be transferred to the heat absorbing plate 131a of the thermoelectric element 131 as the heat moves along the heat pipe 140.

The heat pipe 140 may have a substantially circular or rectangular cross-section. However, the present disclosure is not limited thereto and the heat pipe 140 may have an arc-shaped cross-section to improve contact with the cooking vessel C.

The heat pipe 140 may transfer heat, so that the temperature may be maintained at a high level. In addition, the heat pipe 140 may be located on the outside of the cooking vessel C, there is a risk of burns if the heat pipe 140 comes into contact with the user's skin. Therefore, the sensor device 10 may include a cover 15 or a cover member 15 arranged to enclose the heat pipe 140.

The cover member 15 may be formed of an insulating material to prevent heat from being transferred. For example, the cover member 15 may be formed of a material with low thermal conductivity, such as rubber, plastic, or the like. In addition, the cover member 15 may be formed of an elastic material. The wall surface of the cooking vessel C may be a flat surface or a curved surface having different various curvatures. The cover member 15 may have a predetermined elasticity to be in close contact with the wall surface of the cooking vessel C.

The cover member 15 may include a cover body 151. The cover body 151 may form a receiving space S into which the heat pipe 140 may be inserted. The heat pipe 140 may be in contact with the cooking vessel C from the outside of the cooking vessel C while being inserted into the cover member 15.

The cover body 151 of the cover member 15 may include a holder 152 allowing the sensor device 10 to be mounted on one side of the cooking vessel C. A mounting slot 152a may be formed between the cover body 151 and the holder 152.

One side of the cooking vessel C may be inserted into the mounting slot 152a. As the one side of the cooking vessel C is inserted into the mounting slot 152a, the sensor device 10 may be mounted on the cooking vessel C.

The wall surface of the cooking vessel C may be inserted into the mounting slot 152a. In order for the sensor device 10 to be stably mounted on the cooking vessel C, the perimeter of the mounting slot 152a may be formed of a material, such as rubber with a high friction. Although not shown in the drawings, the mounting slot 152a may be provided with a hook on the inside of the mounting slot 152a in order to be stably mounted on the wall surface of the cooking vessel C for mounting with the cooking vessel C.

The cover member 15 may include an opening portion 153 that is partially open to allow the inside of the cover member 15 to communicate with the mounting slot 152a. The opening portion 153 may include a main body opening portion 1531 formed on the cover body 151 side and a holder opening portion 1532 formed on the holder 152 side. In the present embodiment, both the main body opening portion 1531 and the holder opening portion 1532 are shown as being formed, but the present disclosure is not limited thereto and only the main body opening portion 1531 may be formed.

The main body opening portion 1531 may open a portion of the cover body 151 such that the heat pipe 140 is exposed through the mounting slot 152a. The heat pipe 140 may be arranged to penetrate the cover member 15 and be supported on the heating device 2.

When one side of the cooking vessel C is inserted into the mounting slot 152a, the heat pipe 140 may be exposed from the cover member 15 through the main body opening portion 1531. That is, the main body opening portion 1531 may allow the receiving space S to communicate with the outside. In other words, the heat pipe 140 accommodated in the receiving space S may be exposed through the opening portion 153 and come into contact with one side of the cooking vessel C.

A heat conductor 16 or a heat conducting member 16 may be disposed inside the cover member 15. The heat conducting member 16 may be disposed between the heat pipe 140 and the cooking vessel C. In particular, the receiving space S in which the cover member 15 accommodates the heat pipe 140 may be filled with a thermally conductive material. The heat conducting member 16 may be formed of highly conductive rubber or highly conductive silicone. However, the present disclosure is not limited thereto, and the heat conducting member 16 may include a metallic material. For example, the heat conducting member 16 may be formed of a material with a high thermal conductive material, such as copper, silver, or the like. The heat conducting member 16 may also be provided as a metal segment or the like so as to be in contact with both the cooking vessel C and the heat pipe 140 without being filled within the cover member 15.

The heat conducting member 16 may be arranged to enclose the heat pipe 140. That is, the heat pipe 140 may not be in direct physical contact with the cooking vessel C, but may be in thermal contact via the heat conducting member 16. In other words, the heat conducting member 16 may mediate the transfer of heat conducted from the cooking vessel C to the heat pipe 140.

To increase the contact area between the heat conducting member 16 and the cooking vessel C, the main body opening portion 1531 and the holder opening portion 1532 may be filled with the heat conducting member 16. The main body opening portion 1531 and the holder opening portion 1532 may communicate with each other. That is, the heat conducting member 16 may be filled together in the main body opening portion 1531 and the holder opening portion 1532.

The heat conducting member 16 may receive heat from both the inside and outside of the cooking vessel C inserted in the mounting slot 152a. Such a structure may increase the conduction efficiency of heat from the cooking vessel C to the heat pipe 140.

The heat conducting member 16 may be formed in an arc shape to increase the contact area with the cooking vessel C. In addition, since the wall surface of the cooking vessel C may have different curvatures, the heat conducting member 16 may also have a predetermined elasticity.

The cover member 15 may include a handle portion 15a. The handle portion 15a may be formed on the cover body 151. The user may grasp the handle portion 15a and separate the sensor device 10 mounted on the cooking vessel C. In the present embodiment, the handle portion 15a is provided in the form of a hole, but is not limited thereto.

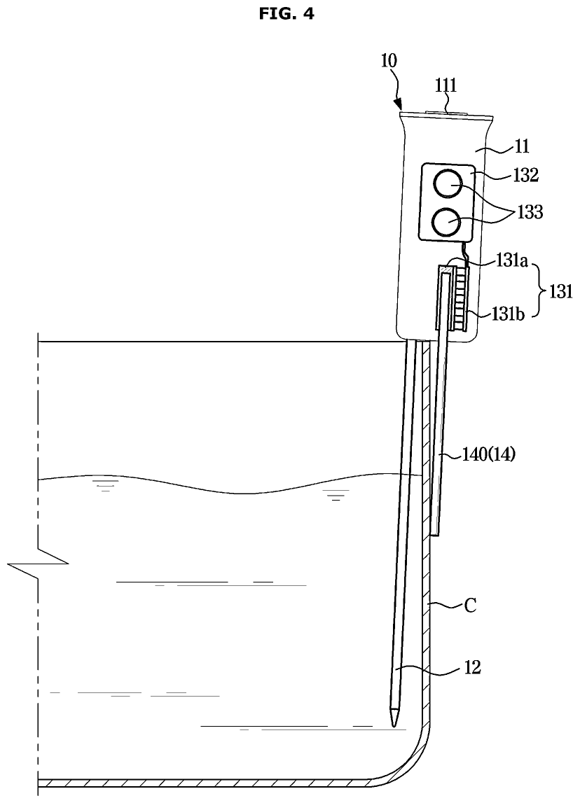

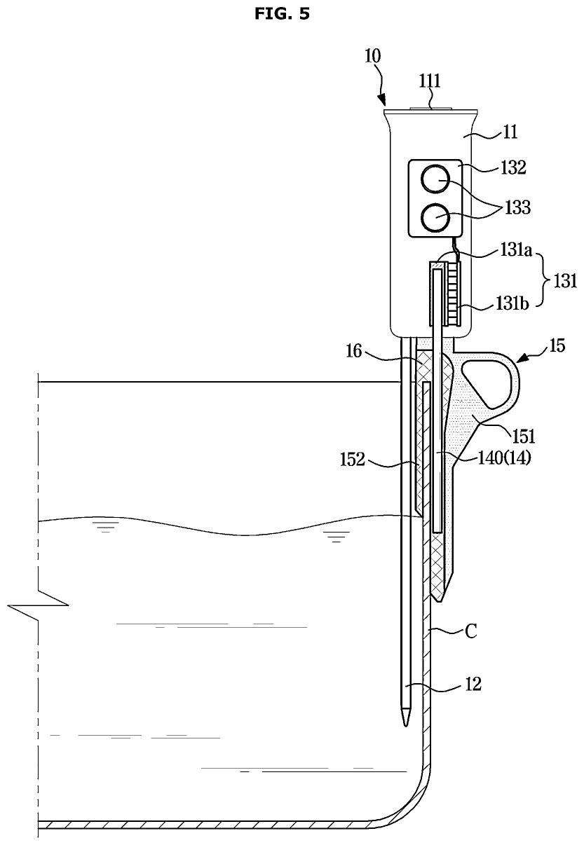

FIGS. 4 and 5 are views to explain a power generation and charging process by showing the sensor device held on the cooking vessel and a direction of heat movement.

With reference to FIGS. 4 and 5, the process of charging the energy storage portion 133 by receiving heat from the cooking vessel C will be described.

The cooking vessel C may be inductively heated by an electromagnetic induction phenomenon. The temperature of the inductively heated cooking vessel C may rise. As the temperature of the cooking vessel C increases, heat may be transferred to the heat pipe 140.

The cooking vessel C may include a metallic material. In other words, the cooking vessel C may have a lower specific heat than the food containing moisture. In other words, it is more efficient to transfer heat from the cooking vessel C than from water, which has a high specific heat. Accordingly, the heat pipe 140 may be disposed on the outside of the cooking vessel C.

The heat pipe 140 may be in contact with the cooking vessel C to receive heat transfer. The portion of the heat pipe 140 in contact with the cooking vessel C may be heated. The portion of the heat pipe 140 through which heat is conducted may have a relatively high temperature. Conversely, a portion of the heat pipe 140 that is far from the portion through which heat is conducted may have a relatively low temperature. A temperature gradient formed within the heat pipe 140 may cause heat to be transferred from a high temperature portion to a low temperature portion. Heat may be transferred by conduction and convection within the heat pipe 140.

The sensor device 10 of FIG. 5 may be mediated by the heat conducting member 16. When the heat conducting member 16 is filled in both the main body opening portion 1531 and the holder opening portion 1532, the contact area with the cooking vessel C may be increased. Accordingly, the heat conduction efficiency may be increased, thereby increasing the amount of heat transferred to the thermoelectric element 131 via the heat pipe 140. In other words, the amount of energy converted into electrical energy is increased, and the energy storage portion 133 may be charged faster.

The heat pipe 140 may be connected to the thermoelectric element 131. In particular, the heat pipe 140 may be connected to the heat absorbing plate 131a of the thermoelectric element 131. That is, heat transferred through the heat pipe 140 may be transferred to the heat absorbing plate 131a.

The thermoelectric element 131 may include the heat dissipating plate 131b separately from the heat absorbing plate 131a. Both the heat absorbing plate 131a and the heat dissipating plate 131b may be metal plates. The heat dissipating plate 131b may include fins for heat dissipation. As the heat absorbing plate 131a continuously absorbs heat from the cooking vessel C and the heat dissipating plate 131b dissipates heat, a temperature difference may be formed.

The thermoelectric element 131 may include semiconductor elements (not shown) between the heat absorbing plate 131a and the heat dissipating plate 131b. In particular, the semiconductor elements (not shown) may be bonded between the heat absorbing plate 131a and the heat dissipating plate 131b to form a closed circuit.

The semiconductor elements (not shown) may include n-type semiconductors and p-type semiconductors. In the n-type semiconductor, electrons, or in the p-type semiconductor, holes, may be moved to the heat absorbing plate 131a, which has a relatively low temperature, respectively. This may allow current to flow in a direction opposite to the movement of the electrons. In other words, thermal energy may be converted into electrical energy by the temperature difference formed in the thermoelectric element 131.

A wire may be connected to the heat absorbing plate 131a. The generated current may be transferred to the PBA 132 through the wire. The PBA 132 may be a step-up circuit. The PBA 132 may step-up the voltage generated by the thermoelectric element 131 to a voltage suitable for charging the energy storage portion 133.

Electrical energy may be stored in the energy storage portion 133 by the output voltage. In this case, electrons may be attached to the anode of the energy storage portion 133, and holes may be attached to the cathode. The energy storage portion 133 may be continuously charged while receiving heat from the cooking vessel C. In other words, the energy storage portion 133 may be charged while using the sensor device 10 by mounting the sensor device 10 on the cooking vessel C. In the case of the energy storage portion 133 being a super capacitor, the energy storage portion 133 may be fully charged in about 3 minutes.

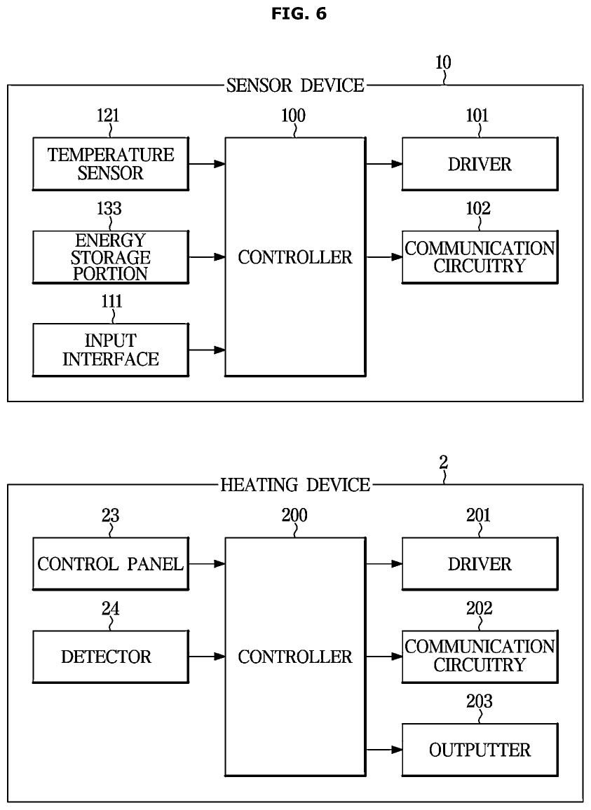

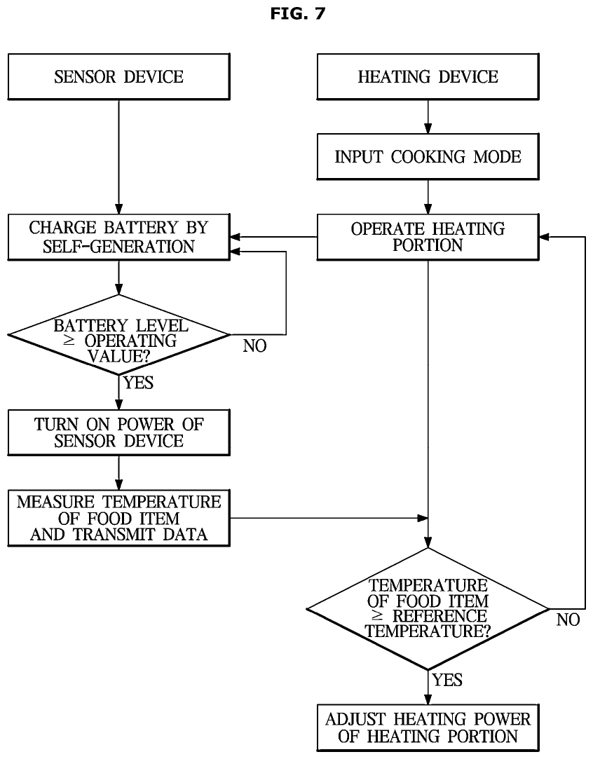

FIG. 6 is a control block diagram for explaining an operation of the sensor device and the heating device according to an embodiment. FIG. 7 is a flowchart for explaining the operation of the sensor device and the heating device according to an embodiment.

With reference to FIGS. 6 and 7, the operation of the sensor device 10 and the heating device 2 will be described.

The sensor device 10 may include the temperature sensor 121, the energy storage portion 133, the input interface 111, a controller 100, a driver 101, and a communication circuitry 102. The temperature sensor 121 may detect the temperature of the food item. Temperature data may be obtained by detecting the temperature of the food item. For example, if the food item is meat, fish, or the like, the temperature within the food item may be measured. If the food item is a liquid, such as broth, soup, stew, or the like, temperature data may be obtained by measuring the temperature of the food item to determine whether it is above the boiling point.

In the energy storage portion 133, data on the remaining energy charged in the energy storage portion 133 (also referred to as ‘state of charge (SoC)’, ‘battery level’) may be measured. A charge level of the energy storage portion 133 may be measured. The method for measuring the charge level of the energy storage portion 133 may include a voltage measurement, a current measurement, and the like.

The input interface 111 may receive input from the user. The input interface 111 may be provided in a variety of ways, such as switches, buttons, touch pads, and the like, but is not limited thereto. The input interface 111 may include a voice recognition module.

The controller 100 may control the overall operation of the sensor device 10. The controller 100 may control the driver 101 and the communication circuitry 102.

The controller 100 may receive temperature data of the food item from the temperature sensor 121. The controller 100 may control the communication circuitry 102 based on the temperature data received from the temperature sensor 121. In addition, the controller 100 may control the driver 101 based on the remaining energy charged in the energy storage portion 133 and/or a signal input to the input interface 111.

The controller 100 of the sensor device 10 may store an operating value for the driver 101 to turn on the power of the sensor device 10. Based on the remaining energy charged in the energy storage portion 133, the driver 101 may turn on the power of the sensor device 10 when the remaining energy charged in the energy storage portion 133 is above the operating value. In addition, the driver 101 may turn off the power of the sensor device 10 when the remaining energy charged in the energy storage portion 133 is below the operating value.

The communication circuitry 102 may enable communication between the sensor device 10 and the heating device 2. The communication circuitry 102 may communicate with a communication circuitry 202 of the heating device 2 by means of Bluetooth, but is not limited thereto. The communication circuitry 102 may communicate in a variety of ways, such as near field communication (NFC), wireless local area network (WLAN), and Zigbee. In the following, the communication circuitry 102 of the sensor device 10 and the communication circuitry 202 of the heating device 2 are described as communicating via Bluetooth.

The communication circuitry 102 may receive the temperature data of the food item measured by the temperature sensor 121 of the sensor device 10 and/or data of the remaining amount of energy charged in the energy storage portion 133. The communication circuitry 102 may communicate with the communication circuitry 202 of the heating device 2 based on the received data.

The communication circuitry 102 of the sensor device 10 may transmit the temperature data of the food item to the communication circuitry 202 of the heating device 2. A controller 200 of the heating device 2 may control the heating power of the cooking zone 22 based on the temperature data of the food item received from the communication circuitry 202. With the desired temperature preset by the user via the input interface 23b, the controller 200 of the heating device 2 may control that the current applied to the coil under the cooking zone 22 is continuously provided until the temperature of the food item detected by the sensor device 10 reaches the temperature preset by the user.

Furthermore, after the temperature of the food item detected by the sensor device 10 reaches the temperature preset by the user, the cooking controller may operate a timer to control the intensity of the current applied to the coil located under the cooking zone 22 to maintain the temperature of the food item for the required time.

In addition, as an example, when the user selects a “soup/stew without boiling over” or “water without boiling over” function via the input interface 23b, the cooking controller may adjust the intensity of the current applied to the coil located under the cooking zone 22 to ensure that the food item inside the cooking vessel C does not overflow the outside of the cooking vessel C.

In another example, when the user selects a “rare/medium/well-done” function for meat via the input interface 23b, the controller 200 of the heating device 2 may adjust the intensity of the current applied to the coil located under the cooking zone 22 to cook the meat to the user's desired condition based on the temperature of the meat detected by the sensor device 10.

The communication circuitry 102 may receive the data of the remaining energy charged in the energy storage portion 133 measured in the energy storage portion 133 of the sensor device 10 and transmit the received data to the communication circuitry 202 of the heating device 2. When the sensor device 10 is heated while being mounted on the cooking vessel C, the energy storage portion 133 of the sensor device 10 may be charged by converting heat energy into electrical energy.

When the remaining energy charged in the energy storage portion 133 of the sensor device 10 is above the operating value, the driver 101 of the sensor device 10 may turn on the power of the sensor device 10. At this time, the communication circuitry 102 of the sensor device 10 may automatically pair with the communication circuitry 202 of the heating device 2 via Bluetooth. However, the present disclosure is not limited thereto, and after the sensor device 10 is turned on, the user may manipulate the input interface 111 to perform Bluetooth pairing with the heating device 2.

The temperature sensor 121 of the sensor device 10 may obtain the temperature data by measuring the temperature of the food item. The controller 100 of the sensor device 10 may receive the temperature data and transmit the received data to the communication circuitry 102. The communication circuitry 102 of the sensor device 10 may transmit the temperature data to the communication circuitry 202 of the heating device 2. The communication circuitry 202 of the heating device 2 may receive the temperature data and transmit the received data to the controller 200. The controller 200 of the heating device 2 may cook the food item based on the received temperature data.

On the other hand, information of the food item may be recognized by the input interface 23b of the heating device 2. The heating device 2 may receive the information of the food item and perform automatic cooking based on the stored food temperature data and/or recipe information. When the power of the sensor device 10 is turned off because the battery level of the sensor device 10 is less than the operating value, the sensor device 10 may be turned on by simply heating the cooking vessel C with the heating device 2, and the sensor device 10 and the heating device 2 may be automatically paired via Bluetooth.

The heating device 2 may include a detector 24 configured to detect the temperature of the cooking vessel C or the temperature of the cooking zone 22. In the event that the temperature of the cooking vessel C or the cooking zone 22 becomes overheated, the detector 24 may transmit a signal to the controller 200, which may cause the controller 200 to adjust the intensity of the current flowing through the coil.

The detector 24 may detect whether the cooking vessel C is placed on the cooking zone 22. When the detector 24 detects a signal input to heat the heating device 2 even though the cooking vessel C is not placed on the cooking zone 22, the detector 24 may transmit the signal to the controller 200 to adjust the intensity of the current flowing through the coil.

An output portion 203 or an outputter 203 may be provided to output the remaining energy charged in the energy storage portion 133 of the sensor device 10. When the communication circuitry 102 of the sensor device 10 transmits data about the remaining energy charged in the energy storage portion 133 to the communication circuitry 202 of the heating device 2, the output portion 203 of the heating device 2 may output the data of the remaining energy charged in the energy storage portion 133. Alternatively, the output portion 203 may output the remaining energy charged in the energy storage portion 133 of the sensor device 10 as a voice.

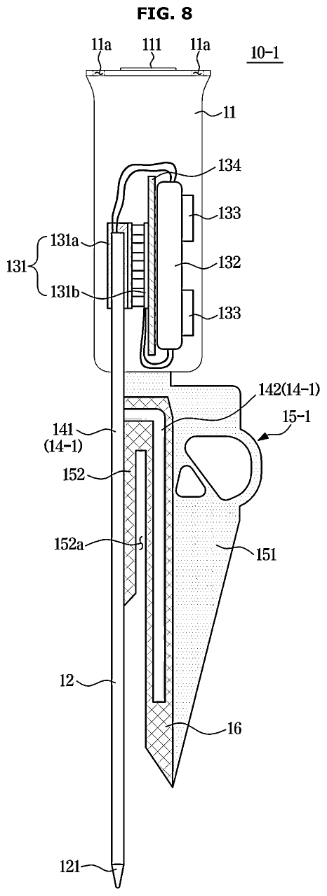

Hereinafter, another embodiment, which is different from the sensor device 10 of FIGS. 1 to 7, will be described. With reference to FIGS. 8 to 10, a sensor device according to another embodiment of the present disclosure will be described. Configurations identical to an embodiment shown in FIGS. 1 to 7 are assigned the same reference numerals, and further description thereof may be omitted.

FIG. 8 is a view illustrating a sensor device according to another embodiment, wherein the heat pipe is disposed within the probe.

A sensor device 10-1 may include a plurality of heat transfer portions 14-1.

The heat transfer portion 14-1 may include a first heat pipe 141 and a second heat pipe 142 extending in parallel to the first heat pipe 141. The sensor device 10-1 may receive heat from the first heat pipe 141 and/or the second heat pipe 142.

The first heat pipe 141 may receive heat from the cooking vessel C. That is, the first heat pipe 141 may be in thermal contact with the cooking vessel C. The second heat pipe 142 may receive heat from the food item. Similarly, the second heat pipe 142 may be in thermal contact with the food item.

The second heat pipe 142 may be disposed within the probe 12. The probe 12 may be positioned inside the cooking vessel C. The probe 12 may measure the temperature of the food item in the cooking vessel C. The second heat pipe 142 may receive heat from the food item because the probe 12 is disposed within the food item to measure the temperature.

In other words, the sensor device 10-1 may receive heat through the first heat pipe 141 and/or the second heat pipe 142. In particular, the first heat pipe 141 may be in contact with a portion of the cooking vessel C to receive heat, and the second heat pipe 142 may receive heat from the food item contained in the cooking vessel C.

The sensor device 10-1 may include an insulating film 134 disposed between the thermoelectric element 131 and the PBA 132. The insulating film 134 may prevent heat transferred to the thermoelectric element 131 from being transferred to the PBA 132. In the present embodiment, the thermoelectric element 131 and the PBA 132 are shown as being disposed side by side, but the present disclosure is not limited thereto. It is sufficient for the insulating film 134 to be disposed between the thermoelectric element 131 and the PBA 132 to prevent heat transferred to the thermoelectric element 131 from being transferred to the PBA 132.

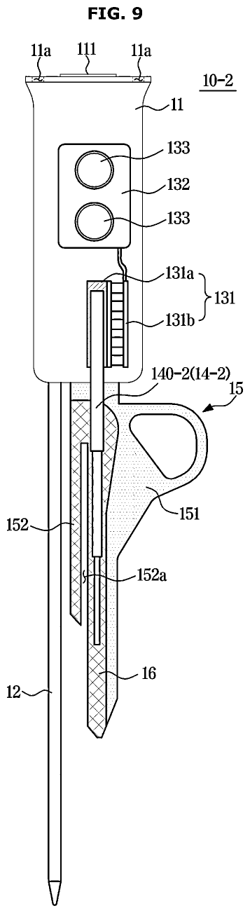

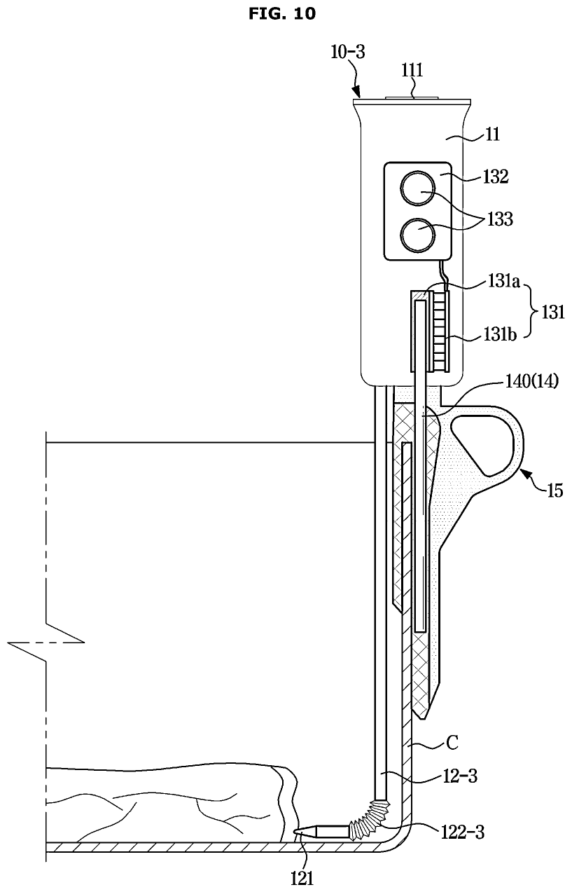

The insulating film 134 may also be included in the sensor device 10 of FIGS. 1 to 7. In addition, the insulating film 134 may also be included in a sensor device 10-2 of FIG. 9 and a sensor device 10-3 of FIG. 10.

FIG. 9 is a view illustrating a sensor device in which the length of the heat pipe is adjustable.

The sensor device 10-2 may include a heat transfer portion 14-2 extendable from the sensor body 11.

The heat transfer portion 14-2 may include a heat pipe 140-2 extendable from the sensor body 11. The heat pipe 140-2 may need to be provided in different lengths depending on the type of cooking vessel C on which the sensor device 10-2 is mounted.

The heat pipe 140-2 may be longer when the cooking vessel C is deep, and may be shorter when the cooking vessel C is shallow. The heat pipe 140-2 may include multiple stages.

The heat pipe 140-2 may include multiple stages with different diameters. The smaller diameter portion of the heat pipe 140-2 may be slidably inserted or withdrawn into the larger diameter portion. In such a way, the length of the heat pipe 140-2 may be adjustable.

FIG. 10 is a view illustrating a sensor device having a bendable end of the probe, wherein the sensor device is mounted on the cooking vessel to measure the temperature of the food item.

In order for the sensor device 10-3 to measure the temperature of a solid food item (e.g., meat, fish, etc.) rather than a liquid food item, it may be necessary for a probe 12-3 of the sensor device 10-3 to be inserted into the food item. Accordingly, the sensor device 10-3 may not measure the temperature of the solid food item when mounted on the cooking vessel C unless the user moves the sensor device 10-3.

The sensor device 10-3 may include the probe 12-3 arranged to be bendable. The probe 12-3 may measure the temperature of the food item, such as meat, fish, or the like, while mounted on the cooking vessel C.

The temperature sensor 121 of the probe 12-3 may be disposed at one end of the probe 12-3, i.e., at an end opposite to the sensor body 11. The probe 12-3 may include a bent portion 122-3 to allow one end of the probe 12-3, at which the temperature sensor 121 is located, to be bent. The bent portion 122-3 may be formed on a portion of the probe 12-3. The bent portion 122-3 may be provided at a location adjacent to the temperature sensor 121. Alternatively, the bent portion 122-3 may also be formed approximately midway along a longitudinal direction of the probe 12-3. However, the present disclosure is not limited thereto, and the bent portion 122-3 may be formed at any portion of the probe 12-3. When the cooking vessel C has a small depth, such as a frying pan, the sensor device 10-3 may measure the temperature of the food item while mounted on the cooking vessel C.

The bent portion 122-3 may be formed as a corrugated structure, as shown in the present embodiment. However, the present disclosure is not limited thereto, and the bent portion 122-3 may be configured as a hinge or the like.

The bent portion 122-3 may be a smooth portion of the probe 12-3 that is bent. That is, the probe 12-3 may have a bent shape rather than a straight rod shape. The angle at which the probe 12-3 is bent may be approximately a right angle.

The sensor device according to an embodiment may include the sensor body 11 including a thermoelectric element 131 that generates a voltage by a temperature difference, the probe 12 mounted on the main body and including the temperature sensor 121 which measures the temperature of the food item contained in the cooking vessel C, the heat pipe 140 which is disposable to be spaced apart from the probe and configured to transfer the heat conducted from the cooking vessel to the thermoelectric element. The main body may include the PBA 132 to which the current generated by the thermoelectric element is applied, and the energy storage portion 133 electrically connected to the PBA. According to the present disclosure, the sensor device may be charged by receiving heat from the heating device. According to the present disclosure, the sensor device may be charged without a separate charger. According to the present disclosure, the sensor device may measure the temperature of the food item.

A portion of the cooking vessel may be positioned between the probe and the heat pipe. According to the present disclosure, the sensor device may be charged by receiving heat from the heating device. According to the present disclosure, the sensor device may be charged simultaneously with temperature measurement.

The battery may include a super capacitor. According to the present disclosure, the battery may be charged or discharged faster.

The sensor device may further include the cover member 15 configured to cover the heat pipe. According to the present disclosure, burns caused by the heat pipe or the like may be prevented.

The insulating cover may include the mounting slot 152a configured to allow the sensor device to be mounted on the cooking vessel. According to the present disclosure, the sensor device may be stably held on the cooking vessel.

The heat pipe may be exposed through the mounting slot so as to be in contact with the cooking vessel.

The sensor device may further include the heat conducting member 16 disposed on the inside of the insulating cover and in contact with a side of the cooking vessel to mediate heat conduction to the heat pipe. According to the present disclosure, the contact area with the cooking vessel may be increased, thereby increasing the heat conduction efficiency.

The sensor device may further include the insulating film 134 that is disposed between the thermoelectric element and the PBA and prevents heat transfer to the PBA. According to the present disclosure, overheating of the PBA may be prevented.

The heat pipe may be configured to extend from the main body. According to the present disclosure, the length of the heat pipe may be adjustable.

The heat pipe may be the first heat pipe 141, and the sensor device may further include the second heat pipe 142 disposed within the probe to transfer heat conducted from the food item to the thermoelectric element. According to the present disclosure, heat may be conducted not only from the cooking vessel but also from the food item.

The temperature sensor may be located at one end of the probe, and the one end of the probe may include the bent portion 122-3 that may be bent. According to the present disclosure, the temperature inside the food item may be measured even when the sensor device is held on the cooking vessel.

The main body may be formed with the heat dissipation hole 11a. According to the present disclosure, heat inside the main body may be dissipated. According to the present disclosure, overheating of the power generation portion may be prevented.

The cooking appliance, on which the cooking vessel is placed, may heat the cooking vessel and the food item, and the heat transferred to the cooking vessel may be stored in the battery via the thermoelectric element and the PBA. The cooking device may include the controller 100 provided to turn on and off the power of the sensor device, wherein the controller may control turning on the power of the sensor device in response to the remaining amount of energy stored in the battery being above the operating value, and charging the battery in response to the remaining amount of energy stored in the battery being below the operating value. According to the present disclosure, the sensor device may be turned on simply by placing the sensor device on the heated cooking vessel.

The cooking appliance may further include the communication circuitry 102 configured to communicate with the cooking appliance in response to the sensor device being turned on, and the communication circuitry may be configured to transmit the temperature value measured by the temperature sensor to the cooking appliance.

The cooking appliance according to an embodiment may include the heating device 2 on which the cooking vessel C containing a food item is placed, and the sensor device 10 provided to be mounted on the cooking vessel. The sensor device may include the probe 12 including the temperature sensor 121 that contacts the food item to measure the temperature of the food item, the power generation portion 13 including the thermoelectric element 131 that converts thermal energy into electrical energy, the PBA 132 to which the current generated by the thermoelectric element is applied, and the energy storage portion 133 electrically connected to the PBA, and the heat pipe 140 configured to transfer heat generated by the cooking vessel to the thermoelectric element, wherein the heat pipe extends spaced apart from the probe and parallel to the probe, the heat pipe having a portion of the cooking vessel being positioned between the probe and the heat pipe. According to the present disclosure, the sensor device may measure the temperature of the food item. According to the present disclosure, the sensor device may be charged by receiving heat from the cooking vessel. According to the present disclosure, the sensor device may be charged simultaneously with temperature measurement.

The sensor device may include the mounting slot 152a provided to be mounted on the cooking vessel, and may further include the cover member 15 provided to expose the heat pipe through the mounting slot. According to the present disclosure, the sensor device may be stably held on the cooking vessel. According to the present disclosure, the sensor device may be charged simultaneously with the temperature measurement.

The sensor device may further include the heat conducting member 16 that is filled inside the insulating cover and is provided to mediate heat conduction to the heat pipe by contacting the cooking vessel. According to the present disclosure, the contact area with the cooking vessel may be increased, thereby increasing the heat conduction efficiency.

The sensor device may further include the controller 100 configured to turn on and off the power of the sensor device, wherein the controller may control turning on the power of the sensor device in response to the remaining amount of energy stored in the battery being above the operating value, and charging the battery in response to the remaining amount of energy stored in the battery being below the operating value. According to the present disclosure, the sensor device may be turned on simply by placing the sensor device on the heated cooking vessel.

The sensor device may further include the communication circuitry 102 configured to communicate with the cooking appliance in response to the sensor device being turned on, and the communication circuitry may be configured to transmit the temperature value measured by the temperature sensor to the cooking appliance.

The battery may include the super capacitor. According to the present disclosure, charging and discharging of the battery may occur rapidly.

According to the present disclosure, the sensor device may measure the temperature of food.

According to the present disclosure, the sensor device may be charged by receiving heat from the cooking vessel.

According to the present disclosure, the sensor device may be charged simultaneously with the temperature measurement.

The effects of the present disclosure are not limited to those mentioned above, and other effects not mentioned will be apparent to those skilled in the art from the following description.

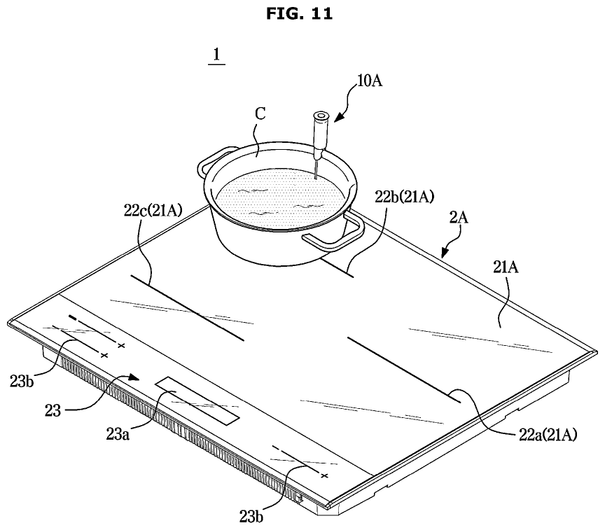

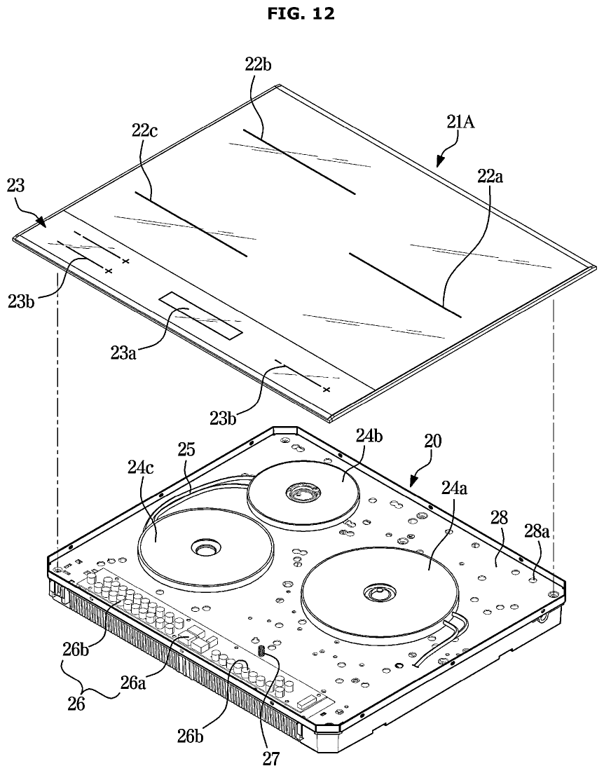

FIG. 11 is a view illustrating an induction heating device, the cooking vessel placed on the induction heating device, and a sensor device mounted to the cooking vessel according to an embodiment of the present disclosure. FIG. 12 is an exploded view illustrating a cooking plate disassembled from the induction heating device of FIG. 11.

Referring to FIGS. 11 and 12, the cooking appliance 1 may include an induction heating device 2A and a sensor device 10A provided to measure the temperature of the food item heated by the induction heating device 2A.

The sensor device 10A according to an embodiment may be used with different types of heating devices 2. The heating device 2 may be provided in any way as long as it can heat a heat transfer portion 14A, which will be described later.

The heating device 2 may be the heating inducing device 2A, but is not limited thereto. For example, the heating device 2 may include a gas burner, a hot plate, a highlighter, or the like. A hot plate may be a heating device in which heat is generated by a hot iron plate itself, and a highlighter may be a heating device in which heat is emitted by a heating wire under a ceramic plate.

When the heating device 2 is configured as a gas burner, a hot plate, a highlighter, and the like, heat may be transferred to the heat transfer portion 14A, and when the heating device 2 is configured as the induction heating device 2A, heat may be generated by inductively heating the heat transfer portion 14A.

As such, the heat transfer portion 14A may be configured to transfer heat generated from an external source to the thermoelectric element 131. In particular, when the heating device 2 is a gas burner, hot plate, highlighter, or the like, it may be a heat source to transfer heat to the heat transfer portion 14A. When the heating device 2 is the induction heating device 2A, it may be a source of a magnetic field to generate heat in the heat transfer portion 14A.

Alternatively, the heating device 2 may be configured to include a gas burner, a hot plate, a highlighter, and an induction heating device. In other words, a cooking zone 22a may be heated by induction heating, and cooking zones 22b and 22c may be heated by a highlighter.

Hereinafter, the heating device 2 will be described as the induction heating device 2A.

The induction heating device 2A may include a main body 20 and a cooking plate 21A disposed on an upper side of the main body 20.

The main body 20 may form part of the exterior of the induction heating device 2A. Induction heating coils 24a, 24b, and 24c may be accommodated in the main body 20 and may generate a magnetic field to inductively heat the cooking vessel C. The induction heating coils 24a, 24b, and 24c may be electrically connected to a main board (not shown) provided inside the main body 20 via a cable 25.

The cooking plate 21A may include cooking zones 22a, 22b, and 22c corresponding to the induction heating coils 24a, 24b, and 24c. The cooking vessel C may be placed on the cooking zones 22a, 22b, and 22c. In other words, the cooking zones 22a, 22b, and 22c may be formed on an upper surface of the cooking plate 21A. The number and location of the cooking zones 22a, 22b, and 22c may be not limited.

The control panel 23 may be provided on the cooking plate 21A. The control panel 23 may provide a user interface for interacting with the user and the induction heating device 2A. The user interface may include at least one input interface 23b and at least one output interface 23a.

The input interface 23b may convert sensory information received from the user into an electrical signal, and may include, for example, a tact switch, a push switch, a slide switch, a toggle switch, a micro switch, a touch switch, a touch pad, a touch screen, a jog dial, and/or a microphone.

The input interface 23b may include a power button, an operation button, a heating power control button, and the like.

The output interface 23a may visually or audibly communicate information related to the operation of a cooking appliance 1 to the user.

The output interface 23a may output a screen, an indicator, a voice, or the like. For example, at least one output interface may include a liquid crystal display (LCD) panel, a light emitting diode (LED) panel, a speaker, or the like.

The induction heating device 2A may include a communication circuitry configured to communicate wired and/or wirelessly with the sensor device 10A. A communication method between the induction heating device 2A and the sensor device 10A will be described later.

The cooking vessel C may be formed of a metal having magnetic properties. When a magnetic field generated by the induction heating coils 24a, 24b, and 24c passes through the metal forming the cooking vessel C, an eddy current may be generated by the resistance of the metal (e.g., iron) of the cooking vessel C. The eddy current generated in the cooking vessel C may generate heat in the cooking vessel C, thereby heating the food item therein.

The cooking vessel C may include a pot, a frying pan, a steamer, a rice cooker, or the like, and the type of cooking vessel C is not limited thereto. A pot will be described herein as an example.

The cooking plate 21A may be arranged in a flat shape to enable the cooking vessel C to be placed on an upper surface thereof. In addition, the cooking plate 21A may be formed of a material having a predetermined heat resistance and strength so as not to be easily damaged by impact, heat, or the like. For example, the cooking plate 21A may be formed of tempered glass, such as ceramic glass.

A circuit board 26 may be disposed on a lower side of the cooking plate 21A. The circuit board 26 may include a display portion 26a and a touch portion 26b.

The display portion 26a may be arranged to correspond to the output interface 23a of the cooking plate 21A. The display portion 26a may display whether the cooking vessel C is heated by the induction heating coils 24a, 24b, and 24c. As a result, the user may check whether the cooking vessel C is heated or not via the output interface 23a.

The touch portion 26b may be arranged to correspond to the input interface 23b provided on the cooking plate 21A. The touch portion 26b may receive a touch signal input from the input interface 23b. For example, the touch portion 26b may receive the input in a capacitive touch manner. However, the present disclosure is not limited thereto, and the touch portion 26b may also receive the input in a pressure sensitive touch manner. The user may adjust the current flowing through the induction heating coils 24a, 24b, and 24c via the input interface 23b and may determine the degree to which the cooking vessel C is heated.

The induction heating coils 24a, 24b, and 24c may be seated on a coil seating plate 28. The coil seating plate 28 may be provided with a coil seating hole 28a for seating the induction heating coils 24a, 24b, and 24c. The coil seating holes 28a may be provided in a plurality.

An elastic member 27 may be disposed above the coil seating plate 28. For example, the elastic member 27 may maintain a spacing distance between the coil seating plate 28 and the cooking plate 21A.

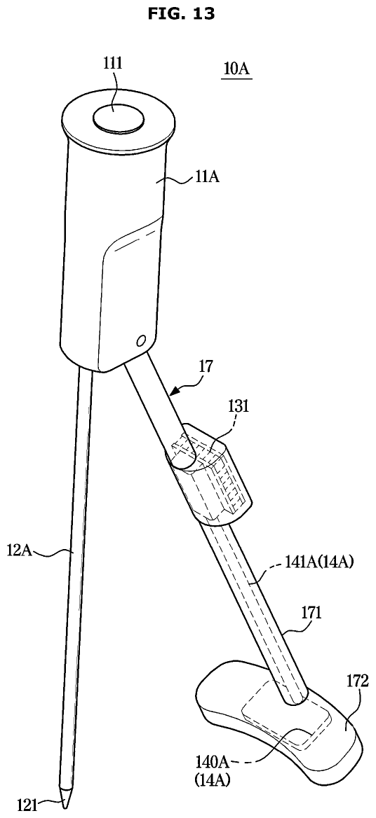

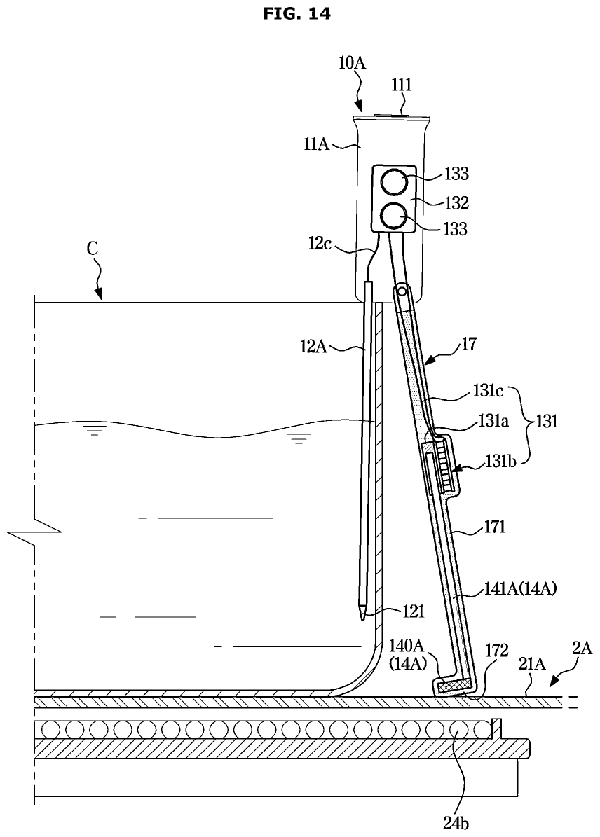

FIG. 13 is a perspective view showing a sensor device according to an embodiment of the present disclosure. FIG. 14 is a cross-sectional view showing the sensor device of FIG. 13 placed on the cooking vessel.

Referring to FIGS. 13 and 14, the sensor device 10A may include a sensor body 11A that is provided to be held by the user. The PBA 132 and the energy storage portion 133, which will be described later, may be disposed within the sensor body 11A.

The sensor body 11A may include the input interface 111 that allows the user to make an input in order to pair the sensor device 10A and the induction heating device 2A. The input interface 111 may be located on an upper side of the sensor body 11A. The input interface 111 may be provided as a button, but is not limited thereto. The input interface 111 may be provided as a touch panel, a switch, or the like.

The sensor device 10A may include a probe 12A mounted on the sensor body 11A to detect the temperature of the food item. The probe 12A may include the temperature sensor 121 therein. The temperature sensor 121 may be provided at one end of the probe 12A. That is, the temperature sensor 121 may be located on the opposite side of the probe 12A from where the probe 12A is secured to the sensor body 11A.

The temperature sensor 121 may be a thermistor whose resistance value varies as a function of temperature. In particular, the temperature sensor 121 may be an NTC thermistor. However, the present disclosure is not limited thereto and may be a PTC thermistor or may be provided as any other type of temperature sensor.

The probe 12A may be formed from a metal that is resistant to heat. For example, the probe 12A may be formed from stainless steel, but is not limited thereto. In addition, the probe 12A may be formed of a waterproof material to prevent liquids from seeping into the interior of the probe 12A.

The probe 12A may be detachably coupled to the sensor body 11A. In particular, one end of the probe 12A may be detachably coupled to the sensor body 11A.

The probe 12A may be provided in the form of a rod. The probe 12A may be formed with a pointed end, i.e., the portion where the temperature sensor 121 is located, to allow the pointed end to be inserted into a food product, such as meat, fish, or the like. However, the present disclosure is not limited thereto, and the probe 12A may also measure the temperature of liquid food, such as broth, soup, stew, or the like.

The probe 12A may include a probe cable 12c that is electrically connected to the PBA 132, which will be described later. The probe cable 12c may transmit the temperature data measured by the temperature sensor 121 to the PBA 132. The probe cable 12c may include an insulating material for heat resistance.

The sensor device 10A may include the power generation portion 13 that generates electrical energy from a temperature difference. The power generation portion 13 may include the thermoelectric element 131 that generates a potential difference due to a temperature difference.

The sensor device 10A may include the thermoelectric element 131 that generates a potential difference due to a temperature difference. The thermoelectric element 131 may be configured to convert thermal energy into electrical energy or electrical energy into thermal energy.

The sensor device 10A may include the PBA 132 to which the current generated in the thermoelectric element 131 is applied, and the energy storage portion 133 electrically coupled to the PBA 132 to store the converted electrical energy.

The thermoelectric element 131 may include the heat absorbing portion 131a to absorb heat and the heat dissipating portion 131b to emit heat. The heat dissipation unit 131b may be maintained at a relatively low temperature as a heat sink.

The heat absorbing portion 131a may be connected to a heat pipe 141A, which will be described later. The heat absorbing plate 131a may receive heat from the heat pipe 141A to form a temperature difference with the heat dissipating plate 131b. The thermoelectric element 131 may generate the Seebeck effect, where electromotive force is generated due to the temperature difference. Electrons may move inside the thermoelectric element 131. This may refer to that current may flow in the thermoelectric element 131.

The thermoelectric element 131 may be electrically connected to the PBA 132. Current generated in the thermoelectric element 131 may flow to the PBA 132. The PBA 132 may include a boost circuit and a regulator circuit.

In addition, the PBA 132 may include a temperature processing circuitry to process the temperature data detected by the temperature sensor 121, and the communication circuitry 102 (see FIG. 6) to enable communication with the induction heating device 2A and/or an external device.

The electromotive force output from the thermoelectric element 131 may be relatively small. Accordingly, the electromotive force generated in the thermoelectric element 131 may be increased by the boost circuit. The increased electromotive force may charge the energy storage portion 133.

The energy storage portion 133 may be a capacitor. However, the present disclosure is not limited thereto and the energy storage portion 133 may be configured as any type of chemical battery. For example, the energy storage portion 133 may be configured as a lithium ion battery, a nickel cadmium battery, or the like. However, due to the nature of use in a high temperature environment, it is preferred to be configured to as a capacitor.

The energy storage portion 133 may be a super capacitor. The super capacitor may refer to a capacitor that has a larger storage capacity than a regular capacitor. In addition, the super capacitor has the advantage that it may be charged and discharged very quickly, may be charged and discharged many times, and may be used semi-permanently.

The sensor device 10A may include a supporter 17 arranged to be spaced apart from the probe 12A. A portion of the cooking vessel C may be located in a space spaced between the probe 12A and the supporter 17. The probe 12A may be located inside the cooking vessel C, and the supporter 17 may be located outside the cooking vessel C, thereby being mounted on the cooking vessel C. In particular, the circumferential surface of the cooking vessel C may be disposed in the spacing space between the probe 12A and the supporter 17.

The supporter 17 may be arranged such that the sensor device 10A is supported on the cooking plate 21A. That is, the supporter 17 may be in physical contact with the cooking plate 21A to support the sensor device 10A.

The supporter 17 may include a material with a high friction, which is in contact with the cooking plate 21A to stably support the sensor device 10A. In addition, the supporter 17 may include a material that is insulating and heat resistant. For example, the supporter 17 may include silicone, rubber, or the like.

A heat generating portion 140A and the heat pipe 141A, which will be described later, may be disposed within the supporter 17. The supporter 17 may prevent the user from being burnt by the heat generated or transferred by the heat generating portion 140A and the heat pipe 141A.

The supporter 17 may include a supporter body 171 extending from the sensor body 11. The supporter body 171 may have a substantially rod shape. The supporter body 171 may extend parallel to the probe 12A.

The supporter body 171 may be hinge-coupled to the sensor body 11A. That is, the supporter body 171 may be rotatable about a hinge coupled to the sensor body 11 as an axis of rotation. In other words, the supporter 17 may be angularly adjustable relative to the probe 12A. Since the supporter 17 is provided so that its angle may be adjusted with respect to the probe 12A, the sensor device 10A may be supported on the cooking plate 21A regardless of the height of the cooking vessel C.

The supporter 17 may include a contact portion 172 provided on a portion of the supporter body 171. The contact portion 172 may be arranged at one end of the supporter body 171. The contact portion 172 may be arranged at an end of the supporter body 171 adjacent to the cooking plate 21. The contact portion 172 may have a cross-sectional area larger than that of the supporter body 171. By ensuring that the contact portion 172 has a contactable area on the cooking plate 21A, the supporter 17 may stably support the sensor device 10A.

The sensor device 10A may include the heat transfer portion 14A configured to transfer heat generated from an external source to the thermoelectric element 131. For example, the external source may be the heated cooking vessel C or the induction heating device 2A. However, the present disclosure is not limited thereto, the external source may be provided in any manner as long as it may generate heat or transfer heat.

The heat transfer portion 14A may include the heat generating portion 140A configured to generate heat by the induction heating device 2A. The heat generating portion 140A may be configured to be inductively heated by a magnetic field generated by the induction heating coil 24b. In other words, the heat generating portion 140A may be a magnetic material. In particular, the heat generating portion 140A may be a magnetic metal. For example, the heat generating portion 140A may include iron or the like.

The heat generating portion 140A may be disposed adjacent to the induction heating coil 24b in order to be inductively heated by the induction heating coil 24b. In other words, the heat generating portion 140A may be located on the inside of the contact portion 172. At least a portion of the heat generating portion 140A may be positioned within the magnetic field area of the induction heating coil 24b while the sensor device 10A is mounted on the cooking vessel C.

In addition, the magnetic field area of the induction heating coil 24b may include an area in which a magnetic field generated by the induction heating coil 24b is formed. The magnetic field area of the induction heating coil 24b may include a vertical area of the induction heating coil 24b and its surroundings.

At least a portion of the heat generating portion 140A may be disposed within the vertical area of the induction heating coil 24b. The vertical area of the induction heating coil 24b may include an upper area perpendicular to the area where the induction heating coil 24b is disposed. In other words, the at least a portion of the heat generating portion 140A may be positioned to overlap the induction heating coil 24b along a vertical direction.

The heat transfer portion 14A may include the heat pipe 141A configured to transfer heat generated by the heat generating portion 140A to the thermoelectric element 131. The heat pipe 141A may be disposed within the supporter 17.

The heat pipe 141A may be thermally connected to the heat generating portion 140A. In other words, the heat pipe 141A may be connected to the heat generating portion 140A to allow heat to move. For example, the heat pipe 141A may receive heat from the heat generating portion 140A by conduction, convection, or radiation.

The heat pipe 141A may be inserted into the heat generating portion 140A. The heat generating portion 140A may be provided with an insertion hole (not shown) into which on end of the heat pipe 141A is inserted. In addition, the heat pipe 141A may be joined to the heat generating portion 140A by welding. For example, when the heat generating portion 140A includes iron and the heat pipe 141A includes copper, they may be joined by a dissimilar metal-to-metal welding.

The heat pipe 141A may transfer heat via conduction and convection. The heat pipe 141A may be configured as a metal pipe with a vacuum inside and a small amount of refrigerant contained therein. For example, a pipe made of copper, which has a high thermal conductivity, may contain a small amount of water.

However, the present disclosure is not limited thereto, the heat pipe 141A may be a metal rod that transfers heat only through conduction. The heat pipe 141A may be made of copper, silver, or the like, having a high thermal conductivity.

When a temperature difference occurs between a heated segment and a cooled segment of a portion of the heat pipe 141A, heat may be transferred by convection of the refrigerant. In one embodiment, heat conducted from the wall surface of the cooking vessel C may be transferred to the heat absorbing portion 131a of the thermoelectric element 131 as it moves along the heat pipe 141A.

The heat pipe 141A may have a substantially circular or rectangular in cross-section. However, the shape of the heat pipe 141A is not limited thereto and may be provided in a variety of shapes.

The heat pipe 141A may be connected to the thermoelectric element 131. In particular, the heat pipe 141A may be connected to the heat absorbing portion 131a of the thermoelectric element 131. In other words, heat transferred through the heat pipe 141A may be transferred to the heat absorbing portion 131a.

The thermoelectric element 131 may include the heat dissipating portion 131b separately from the heat absorbing portion 131a. Both the heat absorbing portion 131a and the heat dissipating portion 131b may be metal plates. The heat dissipating portion 131b may include fins for heat dissipation. Since the heat absorbing portion 131a continuously absorbs heat from the cooking vessel C, and the heat dissipating portion 131b dissipates heat, the temperature difference may be formed.

The thermoelectric element 131 may include semiconductor elements (not shown) between the heat absorbing portion 131a and the heat dissipating portion 131b. In particular, the semiconductor elements (not shown) may be bonded between the heat absorbing portion 131a and the heat dissipating portion 131b to form a closed circuit.

The semiconductor elements (not shown) may include n-type semiconductors and p-type semiconductors. In the n-type semiconductor, electrons, or in the p-type semiconductor, holes, may be moved to the heat absorbing portion 131b, which has a relatively low temperature, respectively. This may allow current to flow in a direction opposite to the movement of electrons. In other words, thermal energy may be converted into electrical energy by the temperature difference formed in the thermoelectric element 131.

The thermoelectric element 131 may include a cable 131c for applying the generated current to the PBA 132. The generated current may be transferred to the PBA 132 through the cable 131c. The PBA 132 may include a boost circuit. The PBA 132 may boost the voltage generated by the thermoelectric element 131 to a voltage suitable for charging the energy storage portion 133.

Electrical energy may be stored in the energy storage portion 133 by the output voltage. In this case, electrons may attach to the anode of the energy storage portion 133, and holes may attach to the cathode.

The energy storage portion 133 may be continuously charged only by operating the induction heating device 2A. In the sensor device 10A, the energy storage portion 133 may be charged by the magnetic field generated by the induction heating device 2A. In other words, the sensor device 10A may be charged by the heat generated by the induction heating device 2A.

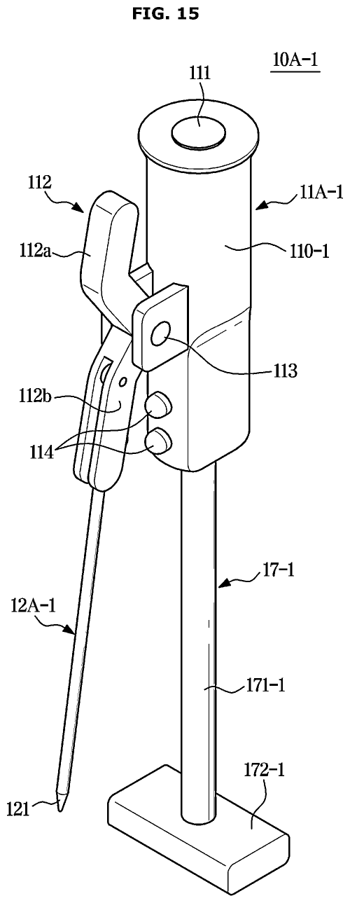

With reference to FIGS. 15 to 18, embodiments different from the sensor device 10A of FIGS. 13 to 14 will be described. In the following, configurations identical to the sensor device 10A of FIGS. 13 and 14 may be omitted from the description, and other configurations will be described in detail.

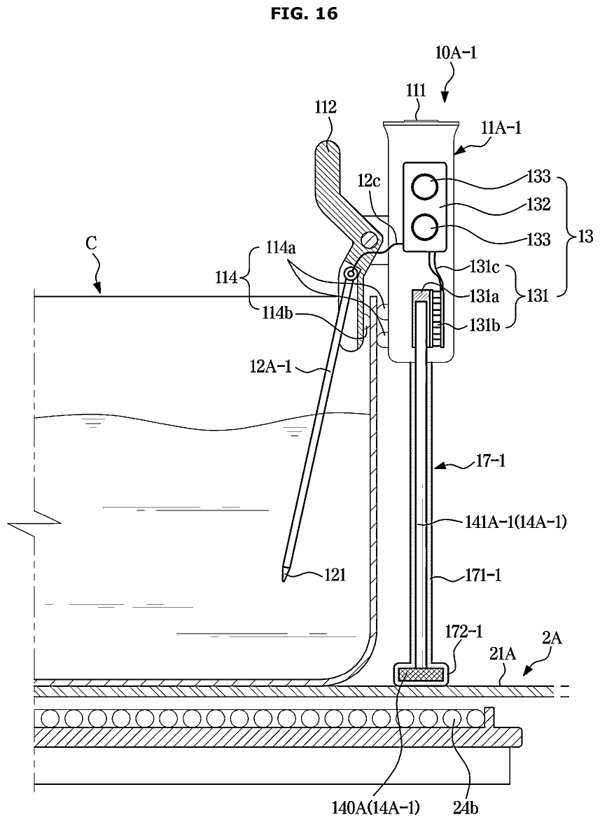

FIG. 15 is a perspective view illustrating a sensor device according to another embodiment of the present disclosure. FIG. 16 is a cross-sectional view illustrating the sensor device of FIG. 15 held on the cooking vessel.

Referring to FIGS. 15 and 16, a sensor device 10A-1 according to another embodiment of the present disclosure may include a sensor body 11A-1 mountable on the cooking vessel C. The sensor body 11A-1 may include a clamping clip 112 to be held on the circumferential surface of the cooking vessel C.

The clamping clip 112 may be coupled to a body portion 110-1 by a torsion spring 113. The clamping clip 112 may be elastically moved by the torsion spring 113. The clamping clip 112 may include a pressing portion 112a provided to be pressed by the user and a holding portion 112b. The torsion spring 113 may be disposed between the pressing portion 112a and the holding portion 112b so that the pressing portion 112a and the holding portion 112b are rotated in opposite directions. For example, upon being pressed by the user against the pressing portion 112a, the holding portion 112b may be released from contact with the cooking vessel C. In addition, upon being released by the user from the pressing portion 112a, the holding portion 112b may be moved into contact with the cooking vessel C by the elastic force of the torsion spring 113.

The sensor body 11A-1 may include a plurality of contact protrusions 114. The plurality of contact protrusions 114 includes a first contact protrusion 114a arranged on the body portion 110-1 and a second contact protrusion 114b arranged on the holding portion 112b. The first contact protrusion 114a and the second contact protrusion 114b may be arranged to contact the cooking vessel C. The first contact protrusion 114a and the second contact protrusion 114b may be formed such that the sensor device 10A-1 is positioned perpendicular to the cooking plate 21. The first contact protrusion 114a and the second contact protrusion 114b may be formed of an insulating material to block heat from the heated cooking vessel C. For example, the first contact protrusion 114a and the second contact protrusion 114b may be formed of silicone, rubber, or the like.

The probe 12A may be arranged on the clamping clip 112. The probe 12 may be rotatably arranged on the clamping clip 112. In other words, one end of the probe 12A may be hinge-coupled to the clamping clip 112. The probe 12A may be arranged to be angularly adjustable with respect to a supporter 17-1 by rotating a hinge about as the axis of rotation. Accordingly, the angle of the probe 12A may be adjustable even when the sensor device 10A-1 is held on the cooking vessel C.

The sensor device 10A-1 may include the supporter 17-1 fixedly arranged on the sensor body 11A-1. The supporter 17-1 may be formed integrally with the sensor body 11A-1. The sensor device 10A-1 may include the thermoelectric element 131 inside the sensor body 11A-1.

The sensor device 10A-1 may include a heat transfer portion 14A-1 extending from the sensor device 10A-1 and arranged to be supported on the induction heating device 2A.

The heat transfer portion 14A-1 may include a heat pipe 141A-1 secured to the heat absorbing portion 131a of the thermoelectric element 131. The heat pipe 141A-1 may connect the thermoelectric element 131 and the heat generating portion 140A. In other words, the heat generating portion 140A may be located at one end of the heat pipe 141A-1, and the thermoelectric element 131 may be located at the other end of the heat pipe 141A-1. The heat generating portion 140A may be located adjacent to the cooking plate 21A. Accordingly, the heat pipe 141A-1 may extend between the cooking plate 21A and the sensor body 11A-1.

The supporter 17-1 may be positioned so that the sensor device 10A-1 is disposed perpendicular to the cooking plate 21A. In other words, the supporter body 171-1 may be positioned perpendicular to the cooking plate 21A. The supporter 17-1 may include a contact portion 172-1 such that the supporter 17-1 may be positioned perpendicular to the cooking plate 21A. The contact portion 172-1 may be arranged perpendicular to the supporter body 171-1.

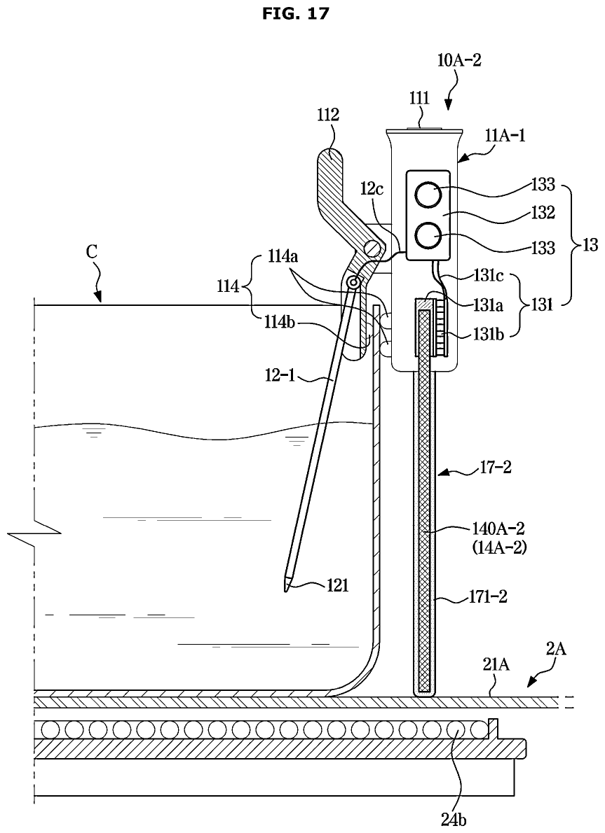

FIG. 17 is a cross-sectional view illustrating the sensor device according to another embodiment of the present disclosure, mounted on the cooking vessel.

Referring to FIG. 17, a sensor device 10A-2 may include a heat transfer portion 14A-2 in contact with the thermoelectric element 131.

The heat transfer portion 14A-2 may be arranged to contact the thermoelectric element 131. The heat transfer portion 14A-2 may include a heat generating portion 140A-2 arranged to be in contact with the thermoelectric element 131.

The heat generating portion 140A-2 may be in contact with the heat absorbing portion 131a of the thermoelectric element 131. In particular, the thermoelectric element 131 may be disposed within the sensor body 11A-1, and the heat generating portion 140A-2 may be fixed to the heat absorbing portion 131a of the thermoelectric element 131. The heat generating portion 140A-2 may be located inside the supporter body 171-2.

The heat generating portion 140A-2 may extend from the heat absorbing portion 131a of the thermoelectric element 131 toward the cooking plate 21A. One end of the heat generating portion 140A-2 may be in contact with the heat absorbing portion 131a of the thermoelectric element 131, and the other end of the heat generating portion 140A-2 may be positioned adjacent to the cooking plate 21A.

The other end of the heat generating portion 140A-2 may be inductively heated by the magnetic field generated by the induction heating coil 24b located below the cooking plate 21A. The heat generated at the other end of the heat generating portion 140A-2 may be transferred to the one end of the heat generating portion 140A-2. The heat transferred to the one end of the heat generating portion 140A-2 may be transferred to the heat absorbing portion 131a of the thermoelectric element 131.

The thermoelectric element 131 may generate electrical energy by the temperature difference between the heat absorbing portion 131a and the heat dissipating portion 131b. In addition, the generated electrical energy may be stored in the energy storage portion 133 via the PBA 132.

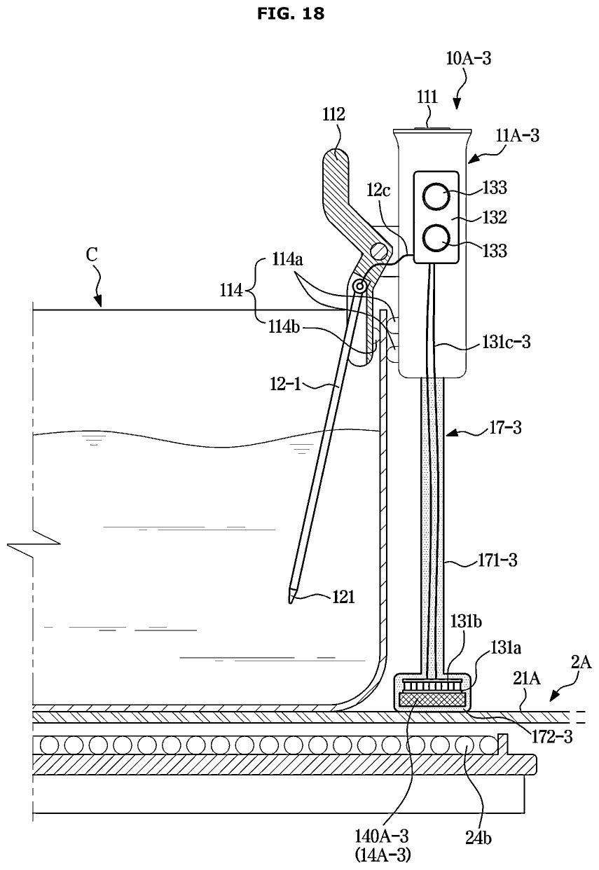

FIG. 18 is a cross-sectional view illustrating a sensor device according to another embodiment of the present disclosure, mounted on the cooking vessel.

Referring to FIG. 18, a sensor device 10A-3 may include a heat transfer portion 14A-3 disposed in contact with the thermoelectric element 131.

The thermoelectric element 131 and the heat generating portion 140A-3 may be disposed within a supporter 17-3. The heat generating portion 140A-3 and the thermoelectric element 131 may be disposed within a contact portion 172-3. The heat generating portion 140A-3 may be located adjacent to the induction heating coil 24b. In other words, the heat generating portion 14-3 may be positioned closer to the induction heating coil 24b than the thermoelectric element 131.

The heat generating portion 140A-3 may be in contact with the heat absorbing portion 131a of the thermoelectric element 131. The heat generating portion 140A-3 may be inductively heated by the magnetic field generated by the induction heating coil 24b. The heat generated by the heat generating portion 140A-3 may be transferred to the heat absorbing portion 131a of the thermoelectric element 131.

The thermoelectric element 131 may generate electrical energy by the temperature difference between the heat absorbing portion 131a and the heat dissipating portion 131b. The thermoelectric element 131 may be electrically connected to the PBA 132 disposed on the sensor body 11A-1 by a cable 131c-3. The electrical energy generated by the thermoelectric element 131 may pass through the PBA 132 and be stored in the energy storage portion 133.

The cooking appliance 1 according to an embodiment may include the main body 20 accommodating an induction heating coil, the cooking plate 21 on which a cooking vessel is placed, wherein the cooking plate 21 includes a cooking zone corresponding to the induction heating coil, and the sensor device 10A configured to be mounted on the cooking vessel. The sensor device may include the thermoelectric element 131 generating a potential difference due to a temperature difference. The sensor device may include the PBA 132 to which current generated by the thermoelectric element is applied. The sensor device may include the energy storage portion 133 electrically connected to the PBA. The sensor device may include the sensor body 11 on which the PBA and the energy storage portion are disposed. The sensor device may include the probe 12 mountable on the sensor body and including the temperature sensor 121 configured to measure the temperature of a food item in the cooking vessel. The sensor device may include the heat generating portion 140A configured to transfer heat generated by a magnetic field generated by the induction heating coil to the thermoelectric element. According to the present disclosure, the sensor device may measure the temperature of the food item. According to the present disclosure, the sensor device may be charged without a separate charger. According to the present disclosure, the sensor device may be charged using the heat generated by the induction heating device. According to the present disclosure, the sensor device may be charged simultaneously with the temperature measurement.

The sensor device may further include the supporter 17 arranged to be spaced apart from the probe, wherein the supporter 17 is configured to allow a portion of the cooking vessel to be positioned between the probe and the supporter. According to the present disclosure, the sensor device may be mounted on a cooking vessel.

The supporter may be configured to enable the sensor device to be supported on the cooking plate. According to the present disclosure, the sensor device may be held on the cooking plate.

The supporter may further include the heat pipe 141A connecting the thermoelectric element and the heat generating portion to transfer heat from the heat generating portion to the thermoelectric element.

The heat generating portion may be located at one end of the heat pipe, and the thermoelectric element may be located at the other end of the heat pipe.

The supporter may include an insulating material. The heat generating portion may be located within the supporter. According to the present disclosure, the risk of burns may be prevented.

The supporter may be hinge-coupled to the sensor body. The supporter may be configured to be angularly adjustable with respect to the probe. According to the present disclosure, the sensor device may be mounted on cooking vessels of different heights.

The supporter may further include the contact portion 172 configured to be supported on the cooking plate. According to the present disclosure, the sensor device may be stably supported.

The thermoelectric element may be disposed in contact with the heat generating portion to enable heat generated by the heat generating portion to be transferred to the thermoelectric element.

The thermoelectric element may be disposed on the sensor body. The heat generating portion may extend from the thermoelectric element toward the cooking plate.

The thermoelectric element may include a heat dissipating portion and a heat absorbing portion. The heat generating portion may be in contact with the heat absorbing portion to enable the heat from the heat generating portion to be transferred.

The sensor body may include the clamping clip 112 to allow the sensor device to be held on the cooking vessel. According to the present disclosure, the sensor device may be held on the cooking vessel.

One end of the probe may be hinge-coupled to the sensor body to enable angle adjustment. According to the present disclosure, the probe may be moved while the sensor device is mounted on the cooking vessel.

The sensor device may be provided such that at least a portion of the heat generating portion may be positioned within a vertical area of the induction heating coil when mounted on the cooking vessel.

The energy storage portion may include a super capacitor.

The sensor device 10 for measuring a temperature of a food item heated by an induction heating device according to an embodiment may include the thermoelectric element 131 generating a potential difference due to a temperature difference, the energy storage portion 133 configured to store the electrical energy converted by the thermoelectric element, the probe 12 including the temperature sensor 121 configured to measure the temperature of the food item, the sensor body 11 on which the probe is mounted and in which the energy storage is disposed, and the heat generating portion 140A including a magnetic element for generating heat by the induction heating device and configured to transfer the heat generated by the induction heating device to the thermoelectric element. According to the present disclosure, the sensor device may measure the temperature of the food item. According to the present disclosure, the sensor device may be charged without a separate charger. According to the present disclosure, the sensor device may be charged using the heat generated by the induction heating device. According to the present disclosure, the sensor device may be charged simultaneously with the temperature measurement.

The sensor device may further include the supporter 17 extending from the sensor body and arranged to be spaced apart from the probe. According to the present disclosure, the sensor device may be mounted on the cooking vessel.

The supporter may further include the heat pipe 141A connected to the thermoelectric element and the heat generating portion to transfer heat from the heat generating portion to the thermoelectric element.

The thermoelectric element may be in contact with the heat generating portion to enable the heat generated by the heat generating portion to be transferred to the thermoelectric element.

The energy storage portion may include a super capacitor.

The sensor device 10 mountable on a cooking vessel for measuring a temperature of a food item in the cooking vessel heated by a heating device according to an embodiment, may include the thermoelectric element 131 generating a potential difference due to a temperature difference, the PBA 132 to which current generated by the thermoelectric element is applied, the energy storage portion 133 electrically connected to the PBA, the sensor body 11 or 11A in which the PBA and the energy storage portion are disposed, the probe 12 mounted on the sensor body and including a temperature sensor and configured to measure the temperature of the food item in the cooking vessel, and the heat transfer portion 14A configured to transfer heat generated from an external source to the thermoelectric element.

The heat transfer portion may be arranged to be spaced apart from the probe to allow one surface of the cooking vessel to be positioned between the probe and the heat transfer portion.

The heat transfer portion may be in contact with the cooking vessel to conduct heat from the cooking vessel.

The probe may extend from the sensor body in one direction, and the heat transfer portion may extend parallel to the probe.

The heat transfer portion may include the heat pipe 140 configured to transfer the heat transferred from the cooking vessel to the thermoelectric element.

The sensor device may further include the cover member 15 covering at least a portion of the heat transfer portion and coupled to the cooking vessel.

The cover member may be arranged to be mounted on the cooking vessel and may include the mounting slot 152a in which a heat conducting member is disposed to conduct heat from the cooking vessel.

The heat transfer portion may include the heat generating portion 140A disposed adjacent to the heating device to be heated by the heating device.

The heat transfer portion may further include the heat pipe 141A configured to transfer the heat generated from the heat generating portion to the thermoelectric element.

The heat transfer portion may extend from the sensor body and be supported on the heating device.

The sensor device may further include the supporter 17 configured to surround the heat transfer portion.

The thermoelectric element may be in contact with the heat transfer portion to allow the heat generated by the heat transfer portion to be transferred to the thermoelectric element.

The heating device may include the induction heating device 2A, and the heat transfer portion may include a magnetic material to generate heat by the induction heating device.

The heat transfer portion may include the heat generating portion 140A disposed adjacent to the induction heating device and formed of the magnetic material, and the heat pipe 141A configured to transfer heat generated by the heat generating portion or to the thermoelectric element.

The energy storage portion may include a super capacitor.

The cooking appliance according to an embodiment may include the heating device on which a cooking vessel is placed, and the sensor device 10 configured to be mounted on the cooking vessel, wherein the sensor device may include the thermoelectric element 131 generating a potential difference due to a temperature difference, the PBA 132 to which current generated by the thermoelectric element is applied, the energy storage portion 133 electrically connected to the PBA, the sensor body 11 in which the PBA and the energy storage portion are disposed, the probe 12 mounted on the sensor body and including a temperature sensor configured to measure the temperature of the food item in the cooking vessel, and the heat transfer portion 14A configured to transfer heat generated from the heating device or from the cooking vessel heated by the heating device to the thermoelectric element.

The heat transfer portion may extend parallel to the probe at a position spaced apart from the probe such that one surface of the cooking vessel is positioned between the heat transfer portion and the probe, and may be arranged to be supported on the cooking vessel or the heating device.

The heat transfer portion may further include the heat pipes 140 and 141A configured to transfer heat to the thermoelectric element.

The cooking appliance may further include the cover member 15 covering at least a portion of the heat pipe and coupled to the cooking vessel, and the heat pipe may be arranged to pass through the cover member and be supported by the heating device.

The energy storage portion may include a super capacitor.

According to the present disclosure, the sensor device may measure the temperature of the food item.

According to the present disclosure, the sensor device may be charged without a separate charger.

According to the present disclosure, the sensor device may be charged using heat generated by the induction heating device.

According to the present disclosure, the sensor device may be charged simultaneously with temperature measurement.

The effects of the present disclosure are not limited to those mentioned above, and other effects not mentioned will be apparent to those of skilled in the art from the following description.

While the present disclosure has been particularly described with reference to exemplary embodiments, it should be understood by those of skilled in the art that various changes in form and details may be made without departing from the spirit and scope of the present disclosure.

What is claimed is:

1. A sensor device mountable on a cooking vessel to measure a temperature of a food item in the cooking vessel heated by a heating device, the sensor device comprising:
a heat transfer portion to receive heat from the heated cooking vessel while the sensor device is mounted to the cooking vessel;
a thermoelectric element to generate a current and electrical energy based on the heat transferred from the heat transfer portion;
a printed board assembly (PBA) to which the current generated by the thermoelectric element is applied;
an energy storage portion electrically connected to the PBA to store the electrical energy received from the PBA;
a sensor body on which the PBA and the energy storage portion are disposed; and
a probe mountable on the sensor body, the probe including a temperature sensor to measure the temperature of the food item in the cooking vessel.

2. The sensor device of claim 1, wherein the heat transfer portion is spaced apart from the probe to allow a part of the cooking vessel to be positioned between the probe and the heat transfer portion.

3. The sensor device of claim 2, wherein the heat transfer portion is in contact with the part of the cooking vessel to conduct the heat from the cooking vessel.

4. The sensor device of claim 2, wherein the probe extends from the sensor body along one direction, and the heat transfer portion extends from the sensor body and in parallel to the probe.

5. The sensor device of claim 2, wherein the heat transfer portion includes a heat pipe configured to transfer the heat transferred from the cooking vessel to the thermoelectric element.

6. The sensor device of claim 4, further comprising a cover configured to cover at least a portion of the heat transfer portion and be mounted to the cooking vessel.

7. The sensor device of claim 6, wherein the cover is mountable on the cooking vessel, and the cover includes a mounting slot in which a heat conductor is disposed to conduct the heat from the cooking vessel.

8. The sensor device of claim 1, wherein the heat transfer portion includes a heat generating portion to be placed adjacent to the heating device to be heated by the heating device.

9. The sensor device of claim 8, wherein the heat transfer portion further includes a heat pipe through which the heat generated by the heat generating portion is transferred to the thermoelectric element.

10. The sensor device of claim 8, wherein the heat transfer portion extends from the sensor body and is supported on the heating device.

11. The sensor device of claim 10, further comprising a supporter configured to enclose the heat transfer portion.

12. The sensor device of claim 1, wherein the thermoelectric element is in contact with the heat transfer portion to allow the heat generated in the heat transfer portion to be transferred to the thermoelectric element.

13. The sensor device of claim 1, wherein
the heating device includes an induction heating device, and
the heat transfer portion includes a magnetic material to enable heat to be generated by the induction heating device.

14. The sensor device of claim 13, wherein the heat transfer portion includes:
a heat generating portion to be placed adjacent to the induction heating device and formed of the magnetic material; and
a heat pipe configured to transfer the heat generated in the heat generating portion to the thermoelectric element.

15. The sensor device of claim 1, wherein the energy storage portion includes a super capacitor.

16. A rechargeable sensor device mountable on a cooking vessel to measure a temperature of a food item in the cooking vessel heated by the heating device, the sensor device comprising:
a sensor body;
a heat transfer portion extending from the sensor body, and to receive heat from the cooking vessel while the sensor device is mounted to the cooking vessel;
a thermoelectric element included in the sensor body, connected to the thermoelectric element, and to convert thermal energy from the received heat into electrical energy;
an energy storage portion included in the sensor body, and to store the converted electrical energy to charge the rechargeable sensor device; and
a probe mountable on the sensor body, the probe including a temperature sensor to measure the temperature of the food item in the cooking vessel,
wherein the temperature sensor is powered on and operated using the electrical energy stored in the energy storage portion.
